(19) United States
(12) Patent Application Publication
(10) Pub. No.: US 2026/0206398 A1
(43) Pub. Date: Jul. 16, 2026

(54) DISPLAY DEVICE AND ELECTRONIC DEVICE

(71) Applicant: Samsung Display Co., LTD., Yongin-si (KR)

(72) Inventors: Sun PARK, Yongin-si (KR); Young Seok SEO, Yongin-si (KR)

(21) Appl. No.: 19/415,100

(22) Filed: Dec. 10, 2025

(30) Foreign Application Priority Data
Jan. 15, 2025 (KR) 10-2025-0005847

(51) Int. Cl. H10H 29/856; H10H 29/855

(52) U.S. Cl. CPC H10H 29/856; H10H 29/8552

(57) ABSTRACT

A display device includes light emitting elements, light extraction structures apart from each other to overlap corresponding light emitting elements, a light blocking layer between the light extraction structures, a reflective layer between each of the light extraction structures and the light blocking layer and around a portion of a side surface of each of the light extraction structures, an organic layer on the light extraction structures and the light blocking layer, a high refractive index layer on the organic layer to overlap the light blocking layer, and a multi-lens layer overlapping the high refractive index layer and the light extraction structures on the organic layer. The multi-lens layer includes one or more first type lenses overlapping a corresponding light extraction structure and having a first curvature and a plurality of second type lenses overlapping the high refractive index layer and having a second curvature different from the first curvature.

### CROSS-REFERENCE TO RELATED APPLICATION

The present application claims priority to and the benefit of Korean Patent Application No. 10-2025-0005847, filed on January 15, 2025, in the Korean Intellectual Property Office, the entire disclosure of which is incorporated herein by reference.

### BACKGROUND

### 1. Field

One or more embodiments of the present disclosure relate to a display device and an electronic device including the display device.

### 2. Description of the Related Art

As the information society continues to advance, the demand for display devices capable of presenting images in various formats has increased. Such display devices may include a flat panel display device, such as a liquid crystal display device, a field emission display device, a light emitting display device, and/or the like.

Light emitting display devices may include organic light-emitting display devices that utilize organic light emitting diode (OLED) elements, and ultra-small light emitting display devices that utilize micro light-emitting diode (micro-LED) elements. Because the micro light emitting diode elements are composed of inorganic materials, they offer advantages such as longer lifespan and/or reduced degradation compared to OLED elements.

### SUMMARY

Aspects and features of embodiments of the present disclosure are directed toward a display device capable of increasing light extraction efficiency.

However, aspects of the present disclosure are not restricted to embodiments set forth herein. The above and other aspects of the present disclosure

will become more apparent to one of ordinary skill in the art to which the present disclosure pertains by referencing the detailed description of the present disclosure provided herein or learning by practice of the presented embodiments of the disclosure.

According to one or more embodiments of the present disclosure, a display device includes a substrate, a transistor layer on (e.g., arranged on )the substrates, a pixel electrode layer on (e.g., arranged on) the transistor layer, a plurality of light emitting elements on (e.g., arranged on) the pixel electrode layer, a plurality of light extraction structures apart (e.g., arranged apart) from each other on the pixel electrode layer to overlap the plurality of light emitting elements, a light blocking layer between (e.g., arranged between) the plurality of light extraction structures, a reflective layer between (e.g., arranged between) the light extraction structures and the light blocking layer and around (e.g., surrounding) at least a portion of side surfaces of each of the plurality of light extraction structures, an organic layer on (e.g., arranged on) the light extraction structures and the light blocking layer, a high refractive index layer on (e.g., arranged on) the organic layer to overlap the light blocking layer; and a multi-lens layer overlapping the high refractive index layer and the light extraction structures on the organic layer, wherein the multi-lens layer includes one or more first type (kind) lenses overlapping a corresponding light extraction structure among the plurality of light extraction structures and having a first curvature and a plurality of second type (kind) lenses overlapping the high refractive index layer and having a second curvature different from the first curvature.

According to one or more embodiments, the second curvature is greater than the first curvature.

According to one or more embodiments, the plurality of second type (kind) lenses surrounds the one or more first type (kind) lenses.

According to one or more embodiments, the first type (kind) lens is arranged to overlap the light emitting element and the second type (kind) lens is arranged to overlap the light blocking layer.

According to one or more embodiments, a width of the first type (kind) lens is wider than a width of the second type (kind) lens and wherein a height of the first type (kind) lens is equal to or lower than a height of the second type (kind) lens.

According to one or more embodiments, a first type (kind) lens and a second type (kind) lens are one selected from among a square, a circle, and an oval. For example, the first type (kind) lens and the second type (kind) lens each independently have a planar shape selected from among a square, a circle, and an oval, (e.g., in plan view).

According to one or more embodiments, a refractive index of the high refractive index layer is higher than a refractive index of the organic layer.

According to one or more embodiments, the high refractive index layer is arranged to surround a periphery of the light emitting element and does not overlap the light emitting element.

According to one or more embodiments, the organic layer has a groove formed downward from a top surface thereof, and the high refractive index layer is arranged in the groove.

According to one or more embodiments, the organic layer includes a first organic layer that flattens (e.g., planarizes) the light extraction structure and the light blocking layer and a second organic layer that is arranged on a top surface of the light extraction structure and flattens (e.g., planarizes) the high refractive index layer.

According to one or more embodiments, each of the plurality of light emitting elements is covered by a corresponding light extraction structure among the plurality of light extraction structures, and wherein a side surface of each of the plurality of light extraction structures includes a reverse tapered slope.

According to one or more embodiments, wherein each of the plurality of light extraction structures is around (e.g., surrounds) at least a portion of a side surface adjacent to a top surface of a corresponding light emitting element among the plurality of light emitting elements.

According to one or more embodiments, each of the plurality of light extraction structures includes a scattering particle.

According to one or more embodiments, an upper edge of each of the plurality of light extraction structures has a rounded shape in a cross-section.

According to one or more embodiments, an upper edge adjacent to a top surface of each of the plurality of light extraction structures is not covered by the reflective layer. For example, the upper edge of each of the plurality of light extraction structures adjacent to its top surface is not covered by the reflective layer.

According to one or more embodiments, an upper edge adjacent to a top surface of each of the plurality of light extraction structures is not covered by the light blocking layer. For example, the upper edge of each of the plurality of light extraction structures adjacent to its top surface is not covered by the light blocking layer.

According to one or more embodiments, the light emitting element further includes: a conductive layer on (e.g., arranged on) a bottom surface of a first semiconductor layer; a protective layer around (e.g., surrounding) the conductive layer and the first semiconductor layer, an active layer, and a second semiconductor layer; a first contact electrode on (e.g., arranged on) the protective layer and connected to the conductive layer exposed without being covered by the protective layer; and a second contact electrode on (e.g., arranged on) the protective layer and arranged in a hole penetrating the conductive layer, the first semiconductor layer, and the active layer,

According to one or more embodiments, the light emitting element further includes; a conductive layer arranged on a bottom surface of a first semiconductor layer, a protective layer around (e.g., surrounding) the conductive layer and the first semiconductor layer, an active layer, and a second semiconductor layer; and a contact electrode on (e.g., arranged on) the protective layer and connected to the conductive layer exposed without being covered by the protective layer, wherein the pixel electrode layer includes a pixel electrode connected to the contact electrode, wherein the display device further includes a common electrode arranged on the light emitting element.

According to one or more embodiments of the present disclosure, an electronic device includes a display panel, a window on (e.g., arranged on) the display panel, and a bottom cover below (e.g., arranged below) the display panel, wherein the display panel includes a substrate, a transistor layer on (e.g., arranged on) the substrate, a pixel electrode layer on (e.g., arranged on) the transistor layer, a plurality of light emitting elements on (e.g., arranged on) the pixel electrode layer, a plurality of light extraction structures apart (e.g., arranged apart) from each other on the pixel electrode layer to overlap the plurality of light emitting elements, a light blocking layer between (e.g., arranged between) the plurality of light extraction structures, a reflective layer between (e.g., arranged between) the light extraction structures and the light blocking layer and around (e.g., surrounding) at least a portion of side surfaces of each of the plurality of light extraction structures, an organic layer on (e.g., arranged on) the light extraction structures and the light blocking layer, a high refractive index layer on (e.g., arranged on) the organic layer to overlap the light blocking layer, and a multi-lens layer overlapping the high refractive index layer and the light extraction structures on the organic layer, wherein the multi-lens layer includes one or more first type (kind) lenses overlapping a corresponding light extraction structure among the plurality of light extraction structures and having a first curvature and a plurality of second type (kind) lenses overlapping the high refractive index layer and having a second curvature different from the first curvature.

According to one or more embodiments, the electronic device further includes a battery in (e.g., arranged in) a space of the bottom cover and supplying power to the display device and a middle frame between (e.g., arranged between) the window and the bottom cover.

According to the display device and the manufacturing method thereof according to one or more embodiments, the amount of light emitted toward a lower side of the light emitting element may be reduced, by the combined effect of the reflective layer and the high refractive index layer, thereby improving the light extraction effect. For example, this configuration enhances the upward emission of light through the light extraction structures and the multi-lens layer. As a result, the light extraction efficiency is improved, leading to increased panel luminance. Accordingly, the panel luminance of the display device may be increased, and the power consumption at the same luminance may be reduced. That is, the display device may, for example, achieve the same luminance with reduced power consumption, thereby improving energy efficiency.

In one or more embodiments, the arrangement of the high refractive index layer, the multi-lens layer, and the light extraction structures is enhanced to form a composite optical path that enhances light extraction efficiency. Specifically, the high refractive index layer acts as an intermediate optical medium that bridges the refractive index difference between the organic layer and the multi-lens layer. This configuration reduces Fresnel reflection losses at the interface and enables more efficient transmission of light through the multi-lens layer. The combination of first-type (kind) and second-type (kind) lenses further tailors the angular distribution of emitted light, improving both brightness and uniformity across the display surface.

However, the effects and aspects of the present disclosure are not limited to the aforementioned effects and aspects, and one or more suitable other effects and aspects are included in the following descriptions of the present disclosure.

### BRIEF DESCRIPTION OF DRAWINGS

The accompanying drawings are included to provide a further understanding of the present disclosure and are incorporated in and constitute a part of the present disclosure. The drawings illustrate embodiments of the present disclosure and, together with the description, serve to explain principles of the present disclosure. Above and/or other aspects will become apparent and more readily appreciated from the following description of example embodiments, taken in conjunction with the accompanying drawings.

FIG. 1 is a perspective view illustrating a display device according to one or more embodiments of the present disclosure.

FIG. 2 is a layout drawing illustrating a display device according to one or more embodiments of the present disclosure.

FIG. 3 is a block drawing illustrating a display device according to one or more embodiments of the present disclosure.

FIG. 4 is an equivalent circuit drawing illustrating a sub-pixel according to one or more embodiments of the present disclosure.

FIG. 5 is a layout drawing illustrating pixels of a display area according to one or more embodiments of the present disclosure.

FIG. 6 is a cross-sectional view illustrating an example cross-section of one display panel corresponding to the lines I-I' in FIG. 5 according to one or more embodiments of the present disclosure.

FIG. 7 is a cross-sectional view illustrating an example of the area A in FIG. 6 in more detail according to one or more embodiments of the present disclosure.

FIG. 8 is a plan view illustrating the multi-lens layer and the high refractive index layer of FIG. 7 according to one or more embodiments of the present disclosure.

FIG. 9 is a cross-sectional view illustrating an example of the area A of FIG. 6 in more detail according to one or more embodiments of the present disclosure.

FIG. 10 is a cross-sectional view illustrating an example of the area A of FIG. 6 in more detail according to one or more embodiments of the present disclosure.

FIG. 11 is a plan view illustrating a relationship between the multi-lens layer and the high refractive index layer of FIG. 10 and surrounding components according to one or more embodiments of the present disclosure.

FIG. 12 is a cross-sectional view illustrating an example of the area A of FIG. 6 in more detail according to one or more embodiments of the present disclosure.

FIG. 13 is a plan view illustrating a relationship between the multi-lens layer of FIG. 12 and surrounding components according to one or more embodiments of the present disclosure.

FIG. 14 is a cross-sectional view illustrating an example of the area A of FIG. 6 in more detail according to one or more embodiments of the present disclosure.

FIG. 15 is a plan view illustrating a relationship between the high refractive index layer of FIG. 14 and surrounding components according to one or more embodiments of the present disclosure.

FIG. 16 is a layout diagram illustrating pixels of a display area according to one or more embodiments of the present disclosure.

FIG. 17 is a cross-sectional view illustrating an example of a cross-section of a display panel corresponding to the line I1-I1’ of FIG. 16 according to one or more embodiments of the present disclosure.

FIG. 18 is a cross-sectional view illustrating an example of the area A2 of FIG. 17 in more detail according to one or more embodiments of the present disclosure.

FIG. 19 and FIG. 20 are each a cross-sectional view illustrating an example of a cross-section of a display panel corresponding to the area A2 of FIG. 16 according to one or more embodiments of the present disclosure.

FIG. 21 and FIG. 22 are each an example view illustrating a smart watch including a display device according to one or more embodiments of the present disclosure.

FIG. 23 is an exploded perspective view of a smart watch including a display device according to one or more embodiments of the present disclosure.

FIG. 24 is an example view of a virtual reality (VR) device including a display device according to one or more embodiments of the present disclosure.

FIG. 25 is an example view of a VR device including a display device according to one or more embodiments of the present disclosure.

FIG. 26 is an example view illustrating a vehicle instrument cluster and center fascia including display devices according to one or more embodiments of the present disclosure.

FIG. 27 is an example view of a transparent display device including a display device according to one or more embodiments of the present disclosure.

### DETAILED DESCRIPTION

Aspects and features of embodiments of the present disclosure and methods of accomplishing the same may be understood more readily by reference to the detailed description of one or more embodiments and the accompanying drawings. Hereinafter, aspects of one or more embodiments will be described in more detail with reference to the accompanying drawings. The described embodiments, however, may be embodied in one or more suitable different forms, and should not be construed as being limited to only the illustrated embodiments herein. Rather, these embodiments are provided as examples so that the present disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure might not be described.

Unless otherwise noted, like reference numerals, characters, or combinations thereof denote like elements throughout the accompanied drawings and the written description, and thus, descriptions thereof will not be repeated for conciseness. Further, parts not related to the description of one or more embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, and/or the like, of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the present disclosure. Thus, embodiments disclosed herein should not be construed as limited to the particular illustrated shapes of regions, but are to include deviations in shapes that result from, for instance, manufacturing.

For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface/interface through which the implantation takes place. Thus, the regions illustrated in the drawings are schematic in nature and their shapes are not intended to illustrate the actual shape of a region of a device and are not intended to be limiting. Additionally, as those skilled in the art would realize, the described embodiments may be modified in one or more suitable different ways, all without departing from the spirit and/or scope of the present disclosure.

In the detailed description, for the purposes of explanation, numerous specific details are set forth to provide a thorough understanding of one or more embodiments. It is apparent, however, that one or more embodiments may be practiced without these specific details or with one or more equivalent arrangements. In other instances, well-established structures and devices are shown in block diagram form to avoid unnecessarily obscuring various embodiments.

Spatially relative terms, such as “beneath,” “below,” “lower,” “under,” “above,” “upper,” and/or the like, may be used herein for ease of explanation to describe one element or feature’s relationship to another element(s) or feature(s) as illustrated in the drawings. It will be understood that the spatially relative terms are intended to encompass different orientations of the device in use or in operation, in addition to the orientation depicted in the drawings. For example, if the device in the drawings is turned over, for example, upside town, elements described as “below” or “beneath” or “under” other elements or features would then be oriented “above” the other elements or features. Thus, the example terms “below” and “under” can encompass both (e.g., simultaneously) an orientation of above and below. The device may be otherwise oriented (e.g., rotated 90 degrees or at other orientations) and the spatially relative descriptors used herein should be interpreted accordingly. Similarly, if (e.g., when) a first part is described as being arranged “on” a second part, this indicates that the first part is arranged at an upper side or a lower side of the second part without the limitation to the upper side thereof on the basis of the gravity direction.

Further, in this disclosure, the phrase “on a plane,” or “in a plan view,” or “in plan view,” refers to viewing a target portion from the top or the above, and the phrase “on a cross-section” refers to viewing a cross-section formed by vertically cutting a target portion from a side.

It will be understood that if (e.g., when) an element, layer, region, or component is referred to as being “formed on,” “on,” “connected to,” or “coupled to” another element, layer, region, or component, it may be directly formed on, on, connected to, or coupled to the other element, layer, region, or component, or indirectly formed on, on, connected to, or coupled to the other element, layer, region, or component such that one or more intervening elements, layers, regions, or components may be present therebetween. In contrast, if (e.g., when) an element is referred to as being "directly on" another element, there may be no intervening element present therebetween. For example, if (e.g., when) a layer, region, or component is referred to as being "electrically connected" or "electrically coupled" to another layer, region, or component, it may be directly electrically connected or coupled to the other layer, region, and/or component, or one or more intervening layers, regions, or components may be present. However, “directly connected/directly coupled” refers to one component directly connecting or coupling another component without an intermediate component. In one or more embodiments, other expressions describing relationships between components such as “between,” “immediately between” or “adjacent to” and “directly adjacent to” may be construed similarly. In addition, it will also be understood that if (e.g., when) an element or layer is referred to as being “between” two elements or layers, it may be the only element or layer between the two elements or layers, or one or more intervening elements or layers may also be present.

For the purposes of the present disclosure, expressions such as “at least one of,” “one of,” and “selected from among,” if (e.g., when) preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, XZ, YZ, and ZZ, or any variation thereof. Similarly, the expression such as "at least one of A and/or B" may include A, B, or A and B. As used herein, the term “and/or” may include any and all combinations of one or more of the associated listed items. For example, the expression such as "A and/or B" and/or “A/B” may include A, B, or A and B. Further, the use of “may” if (e.g., when) describing embodiments of the present disclosure refers to “one or more embodiments of the present disclosure".

It will be understood that, although the terms “first,” “second,” “third,” and/or the like, may be used herein to describe one or more suitable elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section described herein could be termed a second element, component, region, layer, or section, without departing from the spirit and scope of the present disclosure.

In the examples, the x-axis, the y-axis, and/or the z-axis are not limited to three axes of a cubic coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a,” “an,” “one,” and “the” are intended to include the plural forms as well, unless the context clearly indicates otherwise. It will be further understood that the terms “comprise(s),” “comprising,” “has(have),” “having,” “include(s),” and “including,” if (e.g., when) used in this disclosure, specify the presence of the stated features, numbers, steps, operations, elements, and/or components, but do not preclude the presence or addition of one or more other features, numbers, steps, operations, elements, components, and/or groups thereof. Additionally, the terms “comprise(s)/comprising,” “include(s)/including,” “has/have/having,” or other similar terms include or support the terms “consisting of” and “consisting essentially of,” indicating the presence of stated features, numbers, steps, operations, elements, and/or components, without or essentially without the presence of other features, numbers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and refers to within an acceptable range of deviation for the particular value as determined by one of ordinary skill in the art, considering the measurement in question and the error associated with measurement of the particular quantity (i.e., the limitations of the measurement system). For example, “about” may refer to within one or more standard deviations, or within ± 30%, 20%, 10%, or 5% of the stated value. Also, it should be understood that, even if the terms “about,” “approximately,” or “substantially” are not expressly recited in a given element (e.g., a claim element), the scope of such element is intended to include variations that are insubstantial or within the understanding of one of ordinary skill in the art. For example, numerical values and ranges provided herein are intended to include tolerances and measurement uncertainties that would be recognized by those skilled in the art, and the elements (e.g., claim elements) should be construed accordingly to encompass such equivalents.

When one or more embodiments may be implemented differently, a specific process order may be performed differently from the described order. For example, two consecutively described processes may be performed substantially at the same time or performed in an order opposite to the described order.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this disclosure is intended to include all higher numerical limitations subsumed therein. Accordingly, Applicant reserves the right to amend this disclosure, including the claims, to expressly recite any sub-range subsumed within the ranges expressly recited herein. All such ranges are intended to be inherently described in this disclosure such that amending to expressly recite any such subranges would comply with the requirements of 35 U.S.C. § 112(a) and 35 U.S.C. § 132(a).

The electronic or electric devices and/or any other relevant devices or components and/or the device-manufacturing apparatuses according to one or more embodiments of the present disclosure described herein may be implemented utilizing any suitable hardware, firmware (e.g., an application-specific integrated circuit), software, or a combination of software, firmware, and hardware. For example, the one or more suitable components of these devices may be formed on one integrated circuit (IC) chip or on separate IC chips. Further, the one or more suitable components of these devices may be implemented on a flexible printed circuit film, a tape carrier package (TCP), a printed circuit board (PCB), or formed on a substrate.

Further, the one or more suitable components of these devices may be a process or a thread, running on one or more processors, in one or more computing devices, executing computer program instructions and interacting with other system components for performing the one or more suitable functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD- ROM, flash drive, and/and/or the like. Also, a person of skill in the art should recognize that the functionality of one or more suitable computing devices may be combined or integrated into a single computing device, or the functionality of a particular computing device may be distributed across one or more other computing devices without departing from the spirit and scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning for example consistent with their meaning in the context of the relevant art and/or the present disclosure, and should not be interpreted in an idealized or overly formal sense, unless expressly so defined herein.

A person of ordinary skill in the art would appreciate, in view of the present disclosure in its entirety, that each suitable feature of one or more embodiments of the present disclosure may be combined or combined with each other, partially or entirely, and may be technically interlocked and operated in one or more suitable ways, and each embodiment may be implemented independently of each other or in conjunction with each other in any suitable manner unless otherwise stated or implied.

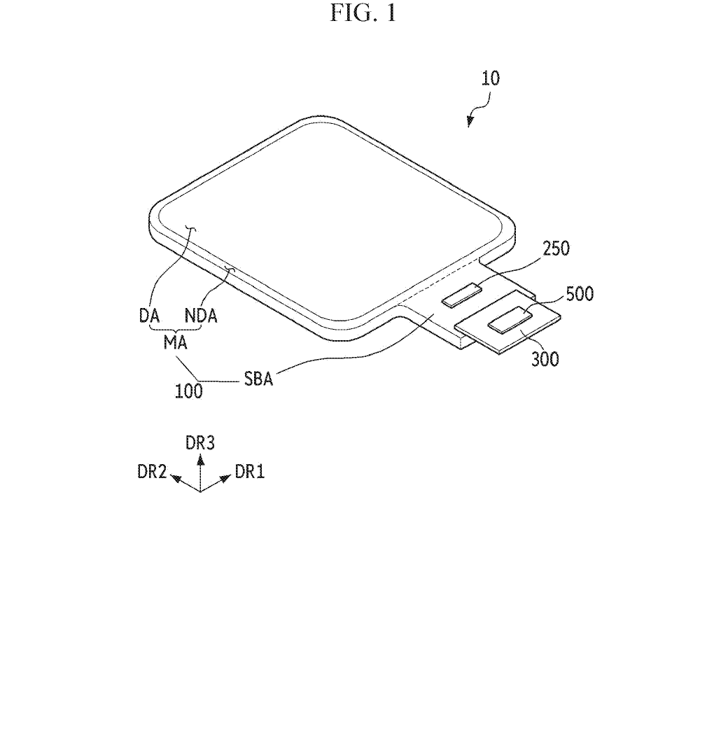

FIG. 1 is a perspective view illustrating a display device according to one or more embodiments of the present disclosure.

Referring to FIG. 1, a display device 10 according to one or more embodiments is a device for displaying video and/or still images, such as a mobile phone, a smart phone, a tablet personal computer, and a portable electronic device such as a smart watch, a watch phone, a mobile communication terminal, an electronic notebook, an e-book, a portable electronic device such as a portable multimedia player (PMP), a navigation device, and/or an ultra-mobile PC (UMPC), as well as a display screen for a variety of products such as televisions, laptops, monitors, billboards, and/or the internet of things (IOT).

In one or more embodiments, the display device 10 may be a light emitting display device, such as an organic light-emitting display device utilizing an organic light-emitting diode (OLED), a quantum dot light-emitting display device including a quantum dot light-emitting layer, an inorganic light-emitting display device including an inorganic semiconductor, or a miniaturized light-emitting display device utilizing a micro or nano light emitting diode (micro LED or nano LED). Hereinafter, the description focuses on embodiments in which the display device 10 is a micro-light emitting display device, but embodiments of the present disclosure are not limited thereto. In this regard, hereinafter, an ultra-small light emitting diode is described as a light emitting element for convenience of explanation.

The display device 10 according to one or more embodiments includes a display panel 100, a display driving circuit 250, a circuit board 300, and a power supply unit (e.g., a power supply circuit) 500.

The display panel 100 may be formed as (or may have) a rectangular shaped plane having a short side in a first direction DR1 and a long side in a second direction DR2 that intersects the first direction DR1. A corner where the short side in the first direction DR1 and the long side in the second direction DR2 meet may be rounded to have (or may have) a suitable curvature (e.g., a set or predetermined curvature) or may be formed at a right angle. The planar shape of the display panel 100 is not limited to a rectangle, for example, may be formed in (or may have) another suitable polygonal shape, a circular shape, or an oval shape. The display panel 100 may be formed flat, but embodiments of the present disclosure are not limited thereto. In one or more embodiments, the display panel 100 may include curved portions with a constant curvature or a changing curvature at left and/or right ends. In one or more embodiments, the display panel 100 may be flexibly formed to be bent, curved, bent, folded, and/or rolled.

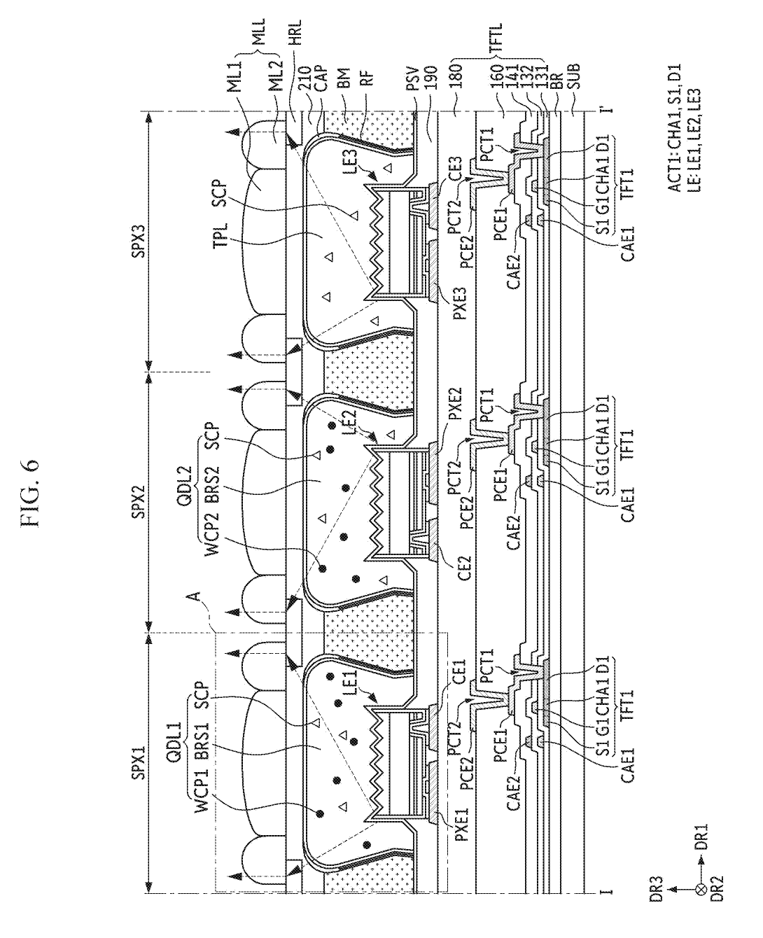

A substrate SUB (e.g., see FIG. 6) of the display panel 100 may include a main area MA and a sub area SBA.

The main area MA may include a display area DA that displays an image and a non-display area NDA that is a surrounding (or peripheral) area of the display area DA. The display area DA may include a plurality of pixels that display an image. Each pixel may include a plurality of sub-pixels. For example, in one or more embodiments, each of the pixels may include a first sub-pixel that is configured to emit light of a first color, a second sub-pixel that is configured to emit light of a second color, and a third sub-pixel that is configured to emit light of a third color. However, embodiments of the present disclosure are not limited thereto.

The sub-area SBA may protrude from a (e.g., one) side of the main area MA in the second direction DR2. Although FIG. 1 illustrates the sub-area SBA being unfolded, in one or more embodiments, the sub-area SBA may be bent, and in this regard, may be arranged on a lower surface of the display panel 100. If (e.g., when) the sub-area SBA is bent, it may overlap the main area MA in a third direction DR3, which is a thickness direction of the display panel 100. The display driving circuit 250 may be arranged in the sub-area SBA.

The display driving circuit 250 may generate signals and voltages for driving the display panel 100. The display driving circuit 250 may be formed as an integrated circuit (IC) and attached to the display panel 100 using a chip on glass (COG) method, a chip on plastic (COP) method, or an ultrasonic bonding method, but embodiments of the present disclosure are not limited thereto. In one or more embodiments, the display driving circuit 250 may be attached to the circuit board 300 using a chip on film (COF) method.

The circuit board 300 may be attached to an (e.g., one) end of the sub-area SBA of the display panel 100. As such, the circuit board 300 may be electrically connected to the display panel 100 and the display driving circuit 250. The display panel 100 and the display driving circuit 250 may receive digital video data, timing signals, and driving voltages through the circuit board 300. In one or more embodiments, the circuit board 300 may be a flexible film, such as a flexible printed circuit board (FPCB), a printed circuit board (PCB), or a chip on film (COF).

The power supply unit 500 may generate a plurality of panel driving voltages according to an external power supply voltage. The power supply unit 500 may be formed as an integrated circuit (IC) and attached to the circuit board 300 using a COF method.

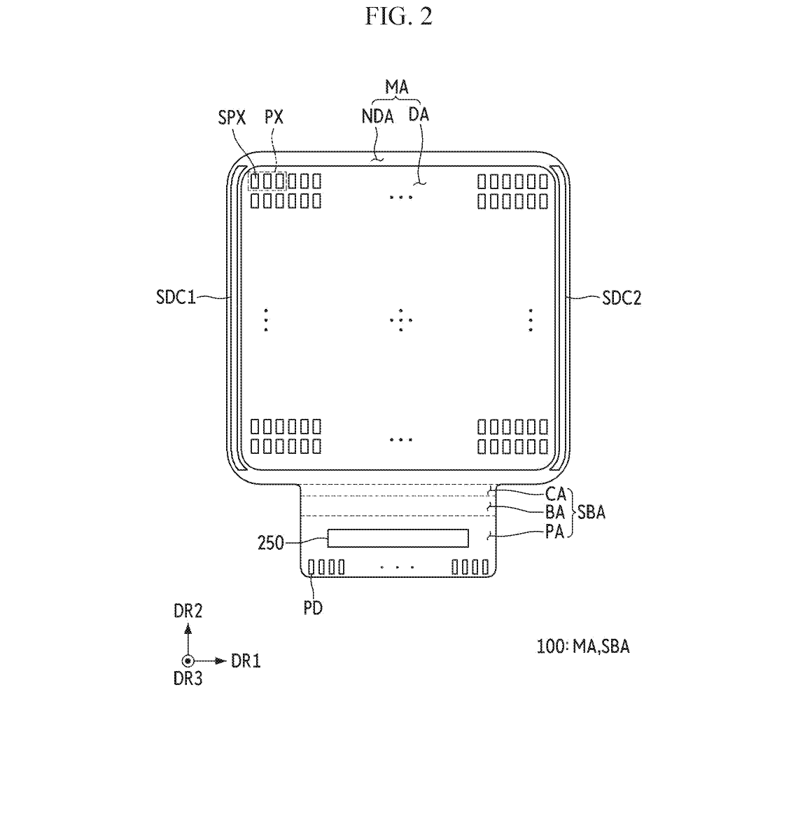

FIG. 2 is a layout drawing illustrating a display device according to one or more embodiments of the present disclosure. FIG. 2 illustrates that the sub-area SBA is unfolded without being bent.

Referring to FIG. 2, the display panel 100 may include the main area MA and the sub-area SBA.

The main area MA may include the display area DA that displays an image and the non-display area NDA that is a peripheral area of the display area DA. The display area DA may occupy most of the main area MA. The display area DA may be placed in the center of the main area MA.

The display area DA includes a plurality of pixels PX for displaying an image, and each of the plurality of pixels PX may include a plurality of sub-pixels SPX. A pixel PX may be defined as a sub-pixel group of the smallest unit capable of expressing grayscale (e.g., a white grayscale).

The non-display area NDA may be placed adjacent to the display area DA. The non-display area NDA may be an area outside the display area DA. In one or more embodiments, the non-display area NDA may be arranged to surround the display area DA. In one or more embodiments, the non-display area NDA may be an edge area of the display panel 100.

A first scan driving portion SDC1 and a second scan driving portion SDC2 may be arranged in the non-display area NDA. The first scan driving portion SDC1 is arranged on one side (e.g., the left side) of the display panel 100, and the second scan driving portion SDC2 is arranged on the other side (e.g., the right side) of the display panel 100. However, embodiments of the present disclosure are not limited thereto.

Each of the first scan driving portion SDC1 and the second scan driving portion SDC2 may be electrically connected to the display driving circuit 250 through scan fan out lines. Each of the first scan driving portion SDC1 and the second scan driving portion SDC2 may receive a scan control signal from the display driving circuit 250, generate scan signals according to the scan control signal, and output them to scan lines.

In one or more embodiments, the sub-area SBA may protrude from one side of the main area MA in the second direction DR2. A length of the sub-area SBA in the second direction DR2 may be smaller than a length of the main area MA in the second direction DR2. A length of the sub area SBA in the first direction DR1 may be less than a length of the main area MA in the first direction DR1 or may be substantially equal to the length of the main area MA in the first direction DR1. In one or more embodiments, the sub-area SBA may be curved and may be arranged at a lower portion of the display panel 100. In these embodiments, the sub-area SBA may overlap the main area MA in the third direction DR3.

The sub-area SBA may include a connection area CA, a pad area PA, and a bending area BA.

The connection area CA is an area protruding from one side of the main area MA in the second direction DR2. One side of the connection area CA may be in contact with the non-display area NDA of the main area MA, and the other side of the connection area CA may be in contact with the bending area BA.

The pad area PA is an area where pads PD and the display driving circuit 250 are arranged. The display driving circuit 250 may be attached to driving pads of the pad area PA using a conductive adhesive member such as an anisotropic conductive film. The circuit board 300 may be attached to the pads PD of the pad area PA using a conductive adhesive member such as an anisotropic conductive film. One side of the pad area PA may be in contact with the bending area BA.

The bending area BA is a bent area. When the bending area BA is bent, the pad area PA may be arranged below the connection area CA and below the main area MA. The bending area BA may be arranged between the connection area CA and the pad area PA. One side of the bending area BA may be in contact with the connection area CA, and the other side of the bending area BA may be in contact with the pad area PA.

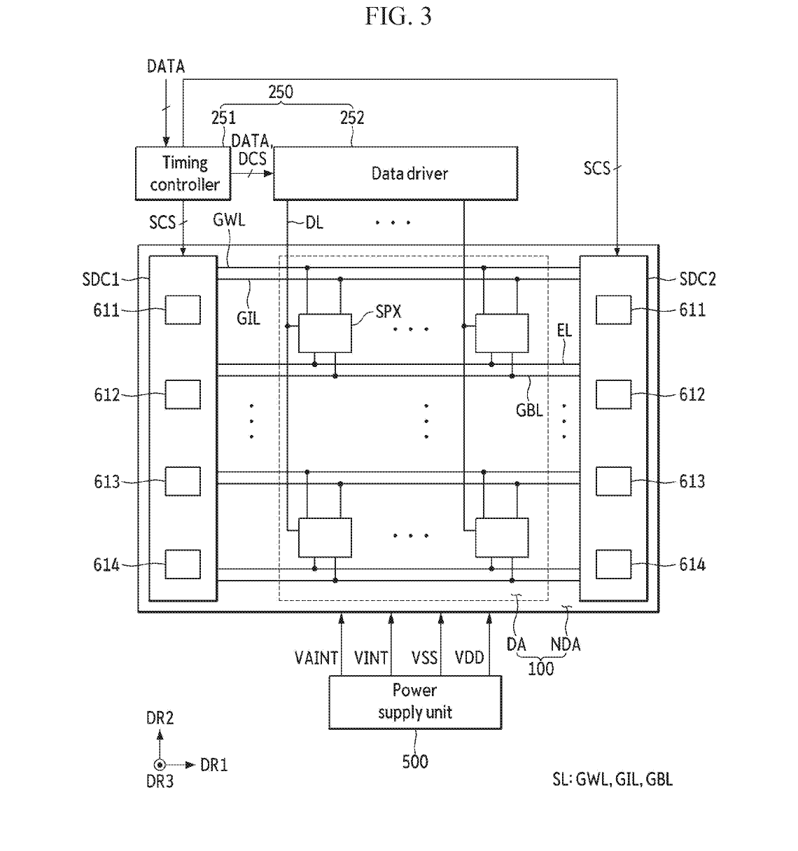

FIG. 3 is a block drawing illustrating a display device according to one or more embodiments of the present disclosure.

Referring to FIG. 2 and FIG. 3, the display area DA includes a plurality of pixels PX including a plurality of sub-pixels SPX, a plurality of scan lines SL, a plurality of emission control lines EL, and a plurality of data lines DL.

The plurality of pixels PX may be arranged in a matrix form along the first direction DR1 and the second direction DR2. For example, in one or more embodiments, the plurality of pixels PX may be arranged along rows and columns of a matrix along the first direction DR1 and the second direction DR2. The plurality of scan lines SL and the plurality of emission control lines EL may extend in the first direction DR1 and may be arranged along the second direction DR2. The plurality of data lines DL may extend in the second direction DR2 and be arranged along the first direction DR1. The plurality of scan lines SL may include a plurality of write scan lines GWL, a plurality of initialization scan lines GIL, and a plurality of bias scan lines GBL. In one or more embodiments, the plurality of scan lines SL may also include a plurality of control scan lines.

Each of the plurality of sub-pixels SPX may be connected to a write scan line GWL selected from among the plurality of write scan lines GWL, an initialization scan line GIL selected from among the plurality of initialization scan lines GIL, a bias scan line GBL selected from among the plurality of bias scan lines GBL, an emission control line EL selected from among the plurality of emission control lines EL, and a data line DL selected from among the plurality of data lines DL. Each of the plurality of sub-pixels SPX may be supplied with a data voltage of the data line DL according to a write scan signal of the write scan line GWL and may be to emit light from a light-emitting element according to the data voltage.

The non-display area NDA includes a first scan driving portion SDC1, a second scan driving unit SDC2, and a display driving circuit 250.

Each of the first scan driving portion SDC1 and the second scan driving portion SDC2 may include a write scan signal output portion 611, an initialization scan signal output portion 612, a bias scan signal output portion 613, and a light emitting signal output portion 614. Each of the write scan signal output portion 611, the initialization scan signal output portion 612, the bias scan signal output portion 613, and the light emitting signal output portion 614 may receive a scan timing control signal SCS from a timing controller 251. The write scan signal output portion 611 may generate write scan signals according to the scan timing control signal SCS of the timing controller 251 and sequentially output them to the write scan lines GWL. The initialization scan signal output portion 612 may generate initialization scan signals according to the scan timing control signal SCS and sequentially output them to the initialization scan lines GIL. The bias scan signal output portion 613 may generate bias scan signals according to the scan timing control signal SCS and sequentially output them to the bias scan lines GBL. The light emitting signal output portion 614 may generate light emitting control signals according to the scan timing control signal SCS and sequentially output them to the emission control lines EL.

The display driving circuit 250 includes the timing controller (e.g., a timing control circuit) 251 and a data driving circuit (i.e., data driver) 252.

The data driving circuit 252 may receive digital video data DATA and a data timing control signal DCS from the timing controller 251. The data driving circuit 252 converts digital video data DATA into analog data voltages according to the data timing control signal DCS and outputs them to the data lines DL. In this regard, the sub-pixels SPX are selected by the write scan signals of the first scan driving unit SDC1 and the second scan driving unit SDC2, and data voltages may be supplied to the selected sub-pixels SPX.

The timing controller 251 may receive digital video data DATA and timing signals from an external source. The timing controller 251 may generate the scan timing control signal SCS and the data timing control signal DCS to control the display panel 100 according to timing signals. The timing controller 251 may output the scan timing control signal SCS to the first scan driving unit SDC1 and the second scan driving unit SDC2. The timing controller 251 may output digital video data DATA and a data timing control signal DCS to the data driving circuit 252.

The power supply unit 500 may generate a plurality of panel driving voltages according to an external power supply voltage. For example, the power supply unit 500 may generate and supply a first driving voltage VDD, a second driving voltage VSS, a third driving voltage VINT, and a fourth driving voltage VAINT to the display panel 100.

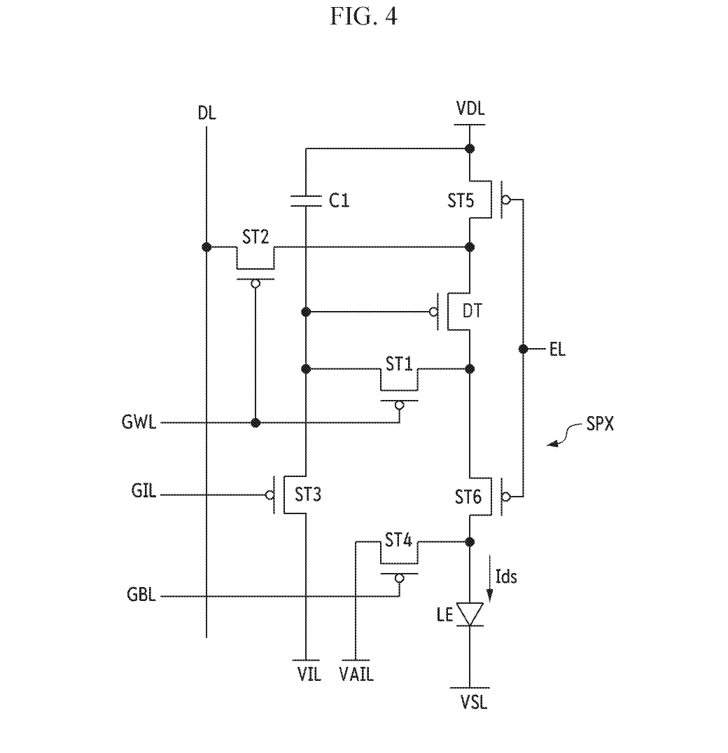

FIG. 4 is an equivalent circuit drawing illustrating a sub-pixel according to one or more embodiments of the present disclosure.

Referring to FIG. 4, the sub-pixel SPX according to one or more embodiments may be connected to scan lines GWL, GIL, and GBL, an emission line EL, and a data line DL. For example, the sub-pixel SPX may be connected to a write scan line GWL, an initialization scan line GIL, a bias scan line GBL, the emission line EL, and the data line DL.

The sub-pixel SPX according to one or more embodiments includes a driving transistor DT, switch elements, a capacitor C1, and a light emitting element LE. The switch elements include first to sixth transistors ST1, ST2, ST3, ST4, ST5, and ST6. The driving transistor DT, switch elements, and capacitor C1 may be referred to as a pixel circuit.

The driving transistor DT includes a gate electrode, a first electrode, and a second electrode. The driving transistor DT controls a drain-source current (Ids, hereinafter referred to as “driving current”) flowing between the first electrode and the second electrode according to a data voltage applied to the gate electrode.

The light emitting element LE may be a micro light emitting diode.

The light emitting element LE emits light according to the driving current Ids. The amount (e.g., emission intensity) of light emitted from the light emitting element LE may be proportional to the driving current Ids. An anode electrode of the light emitting element LE is connected to a first electrode of the fourth transistor ST4 and a second electrode of the sixth transistor ST6, and a cathode electrode thereof may be connected to a second power supply line VSL to which a second power supply voltage (e.g., second driving voltage VSS) is applied.

The capacitor C1 is formed between the gate electrode of the driving transistor DT and a first power supply line VDL to which a first power supply voltage (e.g., first driving voltage VDD) is applied. The first power supply voltage may be at a higher level than the second power supply voltage. One electrode of the capacitor C1 may be connected to the gate electrode of the driving transistor DT, and the other electrode of the capacitor C1 may be connected to the first power supply line VDL.

As shown in FIG. 4, in one or more embodiments, the first to sixth transistors ST1, ST2, ST3, ST4, ST5, and ST6 and the driving transistor DT may all be formed as P-type (kind) metal-oxide-semiconductor field effect transistors (MOSFETs). In these embodiments, an active layer of each of the first to sixth transistors ST1, ST2, ST3, ST4, ST5, and ST6 and the driving transistor DT may be formed of polysilicon.

A gate electrode of the first transistor ST1 and a gate electrode of the second transistor ST2 may be connected to the write scan line GWL, a gate electrode of the third transistor ST3 may be connected to the initialization scan line GIL, a gate electrode of the fourth transistor ST4 may be connected to the bias scan line GBL, and gate electrodes of the fifth and sixth transistors ST5 and ST6 may be connected to the

emission line EL. Because the first to sixth transistors ST1, ST2, ST3, ST4, ST5, and ST6 are each formed as a p-type (kind) MOSFET, they may be turned on if (e.g., when) a scan signal and an emission signal with a gate-low voltage are applied to the initialization scan line GIL, the write scan line GWL, the bias scan line GBL, and the emission line EL, respectively. One electrode of the third transistor ST3 and one electrode of the fourth transistor ST4 may be connected to initialization voltage lines VIL and VAIL, respectively.

In one or more embodiments, the driving transistor DT, the second transistor ST2, the fourth transistor ST4, the fifth transistor ST5, and the sixth transistor ST6 may each be formed of a p-type (kind) MOSFET, and the first transistor ST1 and the third transistor ST3 may each be formed of an N-type (kind) MOSFET. The active layer of each of the driving transistor DT, the second transistor ST2, the fourth transistor ST4, the fifth transistor ST5, and the sixth transistor ST6 formed of P-type (kind) MOSFETs may be formed of polysilicon, the active layer of each of the first transistor ST1 and the third transistor ST3 formed of an N-type (kind) MOSFET may be formed of an oxide semiconductor.

In these embodiments, because the first transistor ST1 and the third transistor ST3 are each formed as N-type (kind) MOSFET, the first transistor ST1 may be turned on if (e.g., when) a scan signal of a gate-high voltage is applied, and the third transistor ST3 may be turned on if (e.g., when) an initialization scan signal of a gate-high voltage is applied. In contrast, the second transistor ST2, the fourth transistor ST4, the fifth transistor ST5, and the sixth transistor ST6 are each formed as P-type (kind) MOSFET, so they may be turned on if (e.g., when) a scan signal of a gate-low voltage and a light emission signal of a gate-low voltage are applied.

In one or more embodiments, the fourth transistor ST4 may be formed of an N-type (kind) MOSFET, so that the active layer of the fourth transistor ST4 may be formed of an oxide semiconductor. When the fourth transistor ST4 is formed of an N- type (kind) MOSFET, it may be turned on if (e.g., when) a scan signal of a gate-high voltage is applied.

In one or more embodiments, the first to sixth transistors ST1, ST2, ST3, ST4, ST5, and ST6 and the driving transistor DT may all be formed as N-type (kind) MOSFET. In these embodiments, the active layer of each of the first to sixth transistors ST1, ST2, ST3, ST4, ST5, and ST6 and the driving transistor DT may be formed of an oxide semiconductor.

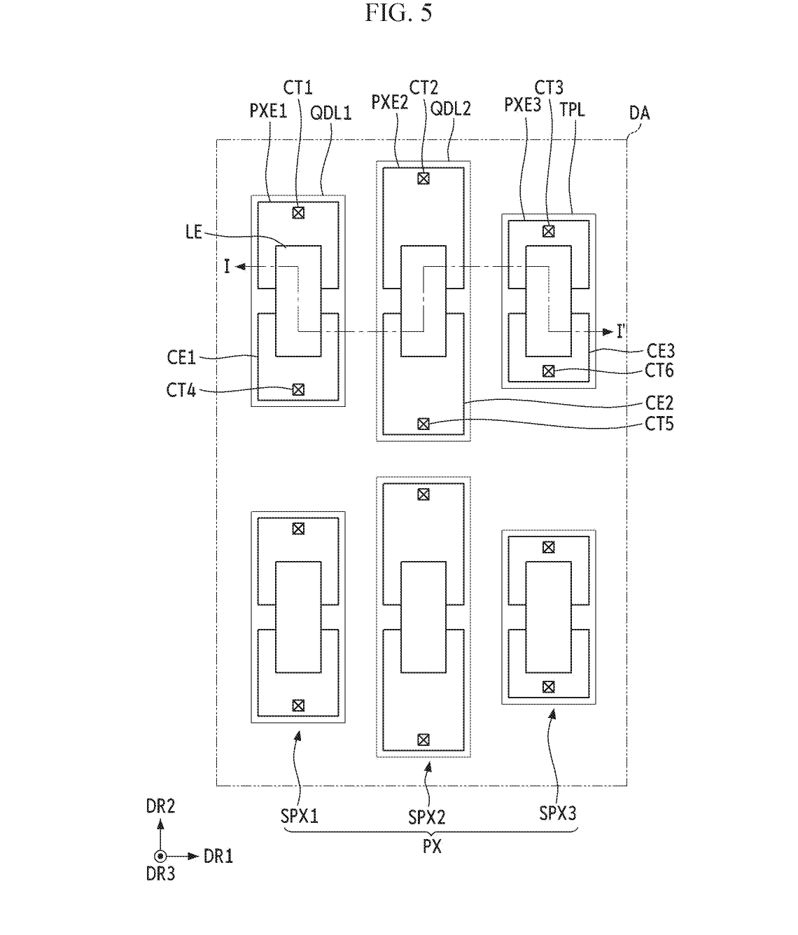

FIG. 5 is a layout diagram illustrating pixels of a display area according to one or more embodiments of the present disclosure.

Referring to FIG. 5, in one or more embodiments, each of the plurality of pixels PX of the display area DA may include three sub-pixels SPX1, SPX2, and SPX3, but embodiments of the present disclosure are not limited thereto, for example, in one or more embodiments, each of the plurality of pixels PX of the display area DA may include four sub-pixels. When each of the plurality of pixels PX includes three sub-pixels SPX1, SPX2, and SPX3, a first sub-pixel SPX1, a second sub-pixel SPX2, and a third sub-pixel SPX3 may be included in the pixel PX.

The plurality of pixels PX may be arranged in a matrix form. In each of the plurality of pixels PX, the first sub-pixel SPX1, the second sub-pixel SPX2, and the third sub-pixel SPX3 may be arranged in the first direction DR1.

When each of the plurality of pixels PX includes three sub-pixels SPX1, SPX2, and SPX3, the first sub-pixel SPX1 may be to emit light of a first color, the second sub-pixel SPX2 may be to emit light of a second color, and the third sub-pixel SPX3 may be to emit light of a third color. Here, the light of the first color may be light in a blue wavelength band, the light of the second color may be light in a green wavelength band, and the light of the third color may be light in a red wavelength band. For example, the blue wavelength band may refer to light having a main peak wavelength in the wavelength band from approximately (about) 370 nanometers (nm) to (about) 460 nm, the green wavelength band may refer to light having a main peak wavelength in the wavelength band from approximately (about) 480 nm to (about) 560 nm, and the red wavelength band may refer to light having a main peak wavelength in the wavelength band from approximately (about) 600 nm to (about) 750 nm.

In one or more embodiments, if (e.g., when) each of the plurality of pixels PX includes four sub-pixels, the first sub-pixel may be to emit light of a first color, the second and fourth sub-pixels may each be to emit light of a second color, and the third sub-pixel may be to emit light of a third color. In one or more embodiments, the first sub-pixel may be to emit light of a first color, the second sub-pixel may be to emit light of a second color, the third sub-pixel may be to emit light of a third color, and the fourth sub-pixel may be to emit light of a fourth color. In this regard, the light of the fourth color light may be white light.

The first sub-pixel SPX1 includes a first pixel electrode PXE1, a plurality of light emitting elements LE, and a first light conversion layer QDL1. The second sub-pixel SPX2 includes a second pixel electrode PXE2, a plurality of light emitting elements LE, and a second light conversion layer QDL2. The third sub-pixel SPX3 includes a third pixel electrode PXE3, a plurality of light emitting elements LE, and a light transmission layer TPL.

In each of the first sub-pixel SPX1, the second sub-pixel SPX2, and the third sub-pixel SPX3, the pixel electrodes PXE1, PXE2, and PXE3 and respective common electrodes CE1, CE2, and CE3 may be arranged in the second direction DR2. In one or more embodiments, each of the pixel electrodes PXE1, PXE2, and PXE3 and the common electrodes CE1, CE2, and CE3 may have a rectangular plane shape, but embodiments of the present disclosure are not limited thereto. In one or more embodiments, an area of the first pixel electrode PXE1 may be substantially the same as an area of the first common electrode CE1, an area of the second pixel electrode PXE2 may be substantially the same as an area of the second common electrode CE2, and an area of the third pixel electrode PXE3 may be substantially the same as an area of the third common electrode CE3, but embodiments of the present disclosure are not limited thereto.

For example, as shown in FIG. 5, if (e.g., when) the light conversion efficiency of the second light conversion layer QDL2 is lower than the light conversion efficiency of the first light conversion layer QDL1, the area of the second pixel electrode PXE2 may be larger than the area of the first pixel electrode PXE1. Furthermore, while the light transmission layer TPL directly transmits the light of the light emitting element LE, the first light conversion layer QDL1 need to convert the light, and therefore the area of the first pixel electrode PXE1 may be larger than the area of the third pixel electrode PXE3 and the area of the first common electrode CE1 may be larger than the area of the third common electrode CE3.

Each of the pixel electrodes PXE1, PXE2, and PXE3 may be electrically connected to at least one transistor through respective pixel connection hole CT1, CT2, or CT3. For example, each of the pixel electrodes PXE1, PXE2, and PXE3 may be electrically connected to the second electrode of the fourth transistor (ST4 in FIG. 4) and the second electrode of the sixth transistor (ST6 in FIG. 4) of the corresponding sub-pixel.

The first common electrode CE1 may be connected to a second power supply line VSL to which a second driving voltage VSS is applied through a first common connection hole CT4. The second common electrode CE2 may be connected to a second power supply line VSL through a second common connection hole CT5. The third common electrode CE3 may be connected to a second power supply line VSL through a third common connection hole CT6. Therefore, the second driving voltage VSS may be applied to each of the common electrodes CE1, CE2, and CE3. The pixel electrodes PXE1, PXE2, and PXE3 may be referred to as an anode electrode or a first electrode, and the common electrodes CE1, CE2, and CE3 may be referred to as a cathode electrode or a second electrode.

A plurality of light emitting elements LE may be arranged on the pixel electrodes PXE1, PXE2, and PXE3 and the common electrode CE1, CE2, and CE3. In one or more embodiments, each of the plurality of light emitting elements LE may have a rectangular planar shape, but embodiments of the present disclosure are not limited thereto. For example, in one or more embodiments, each of the plurality of light emitting elements LE may have a circular planar shape.

The first light conversion layer QDL1 may completely overlap with the plurality of light emitting elements LE of the first sub-pixel SPX1. The first light conversion layer QDL1 may convert or shift the peak wavelength of incident light into light of another specific peak wavelength and emit the light. For example, the first light conversion layer QDL1 may convert or shift third light emitted from the plurality of light emitting elements LE of the first sub-pixel SPX1 into first light.

The second light conversion layer QDL2 may completely overlap with the plurality of light emitting elements LE of the second sub-pixel SPX2. An area of the second light conversion layer QDL2 may be larger than the area of the second pixel electrode PXE2. The second light conversion layer QDL2 may convert or shift the peak wavelength of incident light into light of another specific peak wavelength and emit the light. For example, the second light conversion layer QDL2 may convert or shift the third light emitted from the plurality of light emitting elements LE of the second sub-pixel SPX2 into second light.

The light transmission layer TPL may completely overlap the plurality of light emitting elements LE of the third sub-pixel SPX3. The light transmission layer TPL may directly transmit the incident light. For example, the light transmission layer TPL may directly transmit the third light emitted from the plurality of light emitting elements LE of the third sub-pixel SPX3.

In one or more embodiments, if (e.g., when) the light emitting element LE of the first sub-pixel SPX1 emits light of a first color, the light emitting element LE of the second sub-pixel SPX2 emits light of a second color, and the light emitting element LE

of the third sub-pixel SPX3 emits light of a third color, the light conversion layers QDL1 and QDL2 and the light transmission layer TPL may not be provided.

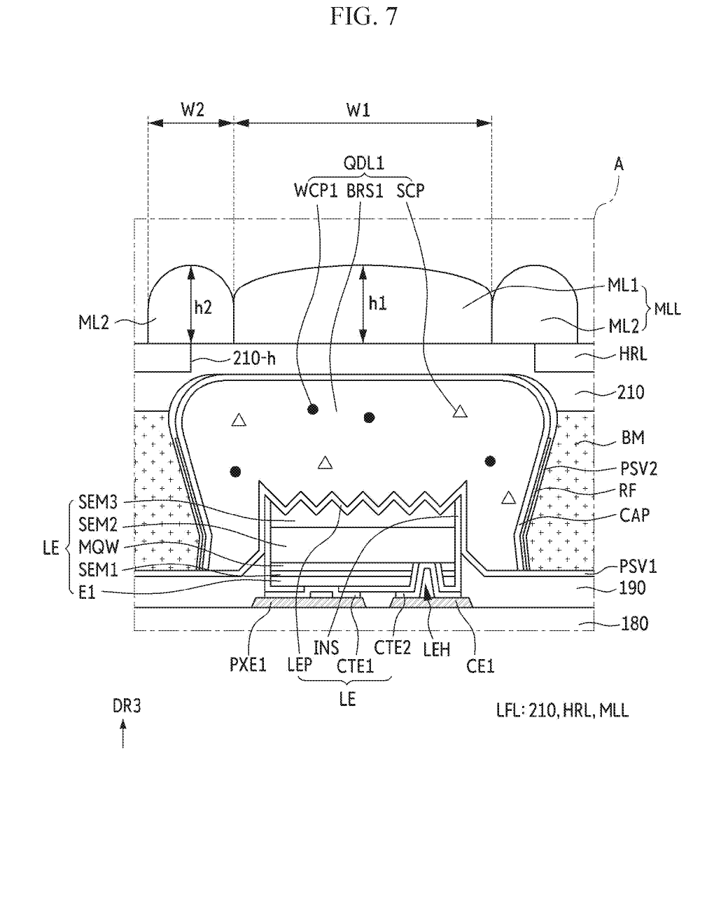

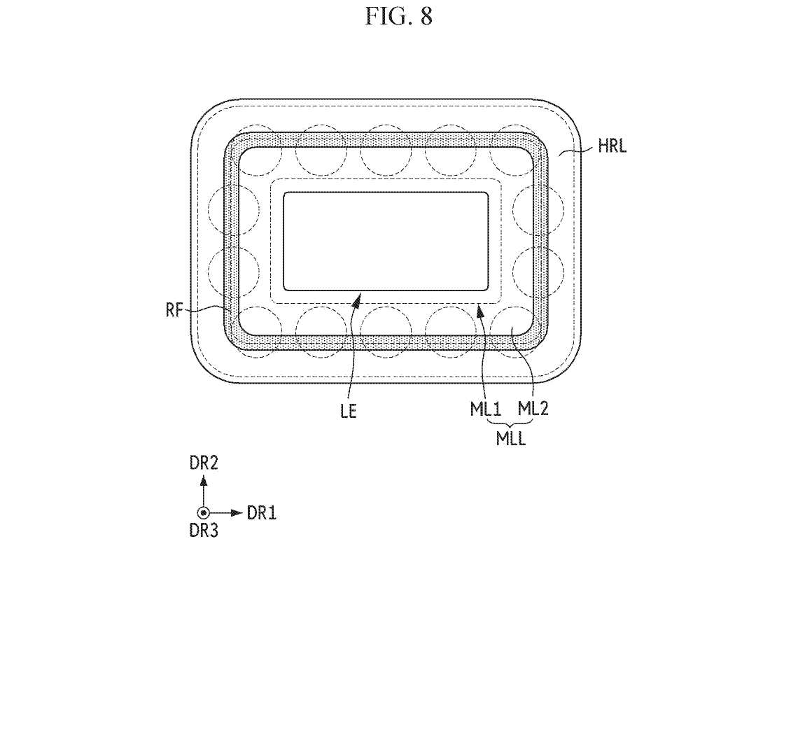

FIG. 6 is a cross-sectional view illustrating an example cross-section of one display panel corresponding to the lines I-I' in FIG. 5 according to one or more embodiments of the present disclosure. FIG. 7 is a cross-sectional view illustrating an example of the area A in FIG. 6 in more detail according to one or more embodiments. FIG. 8 is a plan view illustrating the multi-lens layer and the high refractive index layer of FIG. 7 according to one or more embodiments.

Referring to FIGS. 6 to 8, a substrate SUB may be made of an insulating material such as glass, polymer resin, and/or the like. If (e.g., when) the substrate SUB is made of a polymer resin, it may be a flexible substrate that may be stretched. The polymer resin may be an acrylic resin, an epoxy resin, a phenolic resin, a polyamide resin, a polyimide resin, and/or the like.

A barrier film BR may be arranged on the substrate SUB. The barrier film BR is a film that protects transistors of a thin film transistor layer (i.e., a transistor layer) TFTL from moisture penetrating through the substrate SUB which is vulnerable to moisture permeation. The barrier film BR may be formed of a plurality of inorganic films that are alternately stacked.

A thin film transistor TFT1 may be arranged on the barrier film BR. The thin film transistor TFT1 may be either the fourth transistor ST4 or the sixth transistor ST6 shown in FIG. 4. The thin film transistor TFT1 may include a first active layer ACT1 and a first gate electrode G1.

The first active layer ACT1 of the thin film transistor TFT1 may be arranged on the barrier film BR. In one or more embodiments, the first active layer ACT1 of the thin film transistor TFT1 may include polycrystalline silicon, monocrystalline silicon, low-temperature polycrystalline silicon, or amorphous silicon. In one or more embodiments, the first active layer ACT1 of the thin film transistor TFT1 may include an oxide semiconductor including IGZO (indium (In), gallium (Ga), zinc (Zn), and oxygen (O)), IGZTO (indium (In), gallium (Ga), zinc (Zn), tin (Sn), and oxygen (O)), or IGTO (indium (In), gallium (Ga), tin (Sn), and oxygen (O)).

The first active layer ACT1 may include a first channel area CHA1, a first source area S1, and a first drain area D1. The first channel area CHA1 may be an area overlapping the first gate electrode G1 in the third direction DR3, which is the thickness direction of the substrate SUB. The first source area S1 may be arranged on one side of the first channel area CHA1, and the first drain area D1 may be arranged on the other side of the first channel area CHA1. The first source area S1 and the first drain area D1 may be areas that do not overlap with the first gate electrode G1 in the third direction DR3. The first source area S1 and the first drain area D1 may be conductive areas in which semiconductor materials are doped with ions.

A first gate insulating film 131 may be arranged on the first channel area CHA1, the first source area S1, and the first drain area D1 of the thin film transistor TFT1.

A first gate metal layer may be arranged on the first gate insulating film 131. The first gate metal layer may include the first gate electrode G1 of the thin film transistor TFT1 and a first capacitor electrode CAE1. The first gate electrode G1 may overlap the first active layer ACT1 in the third direction DR3. Although the first gate electrode G1 and the first capacitor electrode CAE1 are illustrated as being arranged apart from each other in FIG. 6, in one or more embodiments, the first gate electrode G1 and the first capacitor electrode CAE1 may be connected to each other.

A second gate insulating film 132 may be arranged on the first gate electrode G1 of the thin film transistor TFT1 and the first capacitor electrode CAE1.

A second gate metal layer may be arranged on the second gate insulating film 132. The second gate metal layer may include a second capacitor electrode CAE2. The second capacitor electrode CAE2 may overlap the first capacitor electrode CAE1 in the third direction DR3. Because the second gate insulating film 132 has a set or predetermined dielectric constant, a capacitor (e.g., C1 in FIG. 4) may be formed by the first capacitor electrode CAE1, the second capacitor electrode CAE2, and the second gate insulating film 132 arranged between them.

A first interlayer insulating film 141 may be arranged on the second capacitor electrode CAE2.

A first data metal layer may be arranged on the first interlayer insulating film 141. The first data metal layer may include a first source connection electrode PCE1. The first source connection electrode PCE1 may be connected to the first drain area D1 of the first active layer ACT1 through a first source contact hole PCT1 penetrating the first gate insulating film 131, the second gate insulating film 132, and the first interlayer insulating film 141.

A first planarization organic film 160 may be arranged on the first source connection electrode PCE1 to planarize a step caused by the thin film transistor TFT1.

A second data metal layer may be arranged on the first planarization organic film 160. The second data metal layer may include a second source connection electrode PCE2. The second source connection electrode PCE2 may be connected to the first source connection electrode PCE1 through a second pixel contact hole (PCT2) penetrating the first planarization organic film 160.

A second planarization organic film 180 may be arranged on the second source connection electrode PCE2.

The barrier film BR, the first gate insulating film 131, the second gate insulating film 132, and the first interlayer insulating film 141 may each be formed of an inorganic film, such as silicon nitride (SiNₓ), silicon oxide nitride (SiON), silicon oxide (SiOₓ), titanium oxide (TiOₓ), or aluminum oxide (AlOₓ).

The first gate metal layer, the second gate metal layer, the first data metal layer, and the second data metal layer may each be formed as a single layer or multiple layers of any one selected from among molybdenum (Mo), aluminum (Al), chromium (Cr), gold (Au), titanium (Ti), nickel (Ni), neodymium (Nd), and copper (Cu), or an alloy thereof.

The first planarization organic film 160 and the second planarization organic film 180 may each be formed of an organic film such as an acrylic resin, an epoxy resin, a phenolic resin, a polyamide resin, a polyimide resin, and/or the like.

A light emitting element layer may be arranged on the second planarization organic film 180. The light emitting element layer may include pixel electrodes PXE1, PXE2, PXE3, light emitting elements LE, and a common electrode CE (i.e., CE1, CE2, CE3),

A pixel electrode layer including pixel electrodes PXE1, PXE2, and PXE3 and common electrodes CE1, CE2, and CE3 may be arranged on the second planarization organic film 180.

Each of the first pixel electrode PXE1, the second pixel electrode PXE2, and the third pixel electrode PXE3 may be connected to a second source connection electrode PCE2 through a respective connection hole (CT1/CT2/CT3 in FIG. 5) penetrating the second planarization organic film 180. Each of the pixel electrodes PXE1, PXE2, and PXE3 may be connected to a first source area S1 or a first drain area D1 of a thin film transistor TFT1 through the first source connection electrode PCE1 and the second source connection electrode PCE2. Therefore, a voltage controlled or selected by the thin film transistor TFT1 may be applied to each of the pixel electrodes PXE1, PXE2, and PXE3.

The common electrodes CE1, CE2, and CE3 may be connected to a second power supply line (VSL in FIG. 4) to which a second driving voltage (VSS in FIG. 3) is applied through a common connection hole (CT4/CT5/CT6 in FIG. 5). For example, the first common electrode CE1 may be connected to the second power supply line VSL through the second common connection hole CT4. The second common electrode CE2 may be connected to the second power supply line VSL through the second common connection hole CT5. The third common electrode CE3 may be connected to the second power supply line VSL through the third common connection hole CT6. Therefore, the second driving voltage VSS may be applied to each of the common electrodes CE1, CE2, and CE3.

The pixel electrode layer may be formed as a single layer or multiple layers of any one selected from among molybdenum (Mo), aluminum (Al), chromium (Cr), gold (Au), titanium (Ti), nickel (Ni), neodymium (Nd), and copper (Cu), or alloys thereof. For example, in one or more embodiments, the pixel electrode layer may be made of copper (Cu) having low surface resistance to lower the resistance of each of the pixel electrodes PXE1, PXE2, and PXE3.

A light emitting element LE may be arranged on each pixel electrode layer. In FIG. 6 and FIG. 7, the light emitting element LE is illustrated as a flip-type (kind) micro LED. The flip-type (kind) micro LED refers to an LED in which contact electrodes CTE1 and CTE2 are formed on one side (e.g., a bottom side) of the light emitting element LE.

Each of the plurality of light emitting elements LE may be formed from an inorganic material such as gallium nitride (GaN).

In one or more embodiments, each of the plurality of light emitting elements LE may be formed by growing on a semiconductor substrate such as a silicon substrate or a sapphire substrate. The plurality of light emitting elements LE may be transferred onto the pixel electrode layer of the display panel 100 directly from the semiconductor substrate or through a relay substrate. In one or more embodiments, the plurality of light emitting elements LE may be transferred onto the pixel electrode layer of the display panel 100 by an electrostatic method using an electrostatic head or a stamp method using an elastic polymer material such as polydimethylsiloxane (PDMS) or silicone as a transfer substrate.

In one or more embodiments, a reflective layer may be arranged on a top surface of the pixel electrode PXE1 and a top surface of the common electrode CE1.

The reflective film may reflect light traveling downward from the light emitting element LE and emit light to a top surface of the light emitting element LE. Therefore, because the light loss of the light emitting element LE may be reduced, the light efficiency of the light emitting element LE may be increased.

The reflective film may be formed as a single layer of a metal having high reflectivity or may be formed as a multilayer such as titanium (Ti)/aluminum (Al)/titanium (Ti) or ITO/aluminum (Al)/ITO.

The light emitting element LE may include a conductive layer E1, a first semiconductor layer SEM1, an active layer MQW, a second semiconductor layer SEM2, a third semiconductor layer SEM3, a first contact electrode CTE1, a second contact electrode CTE2, and a protective film INS.

The conductive layer E1 may be arranged on a bottom surface of the first semiconductor layer SEM1. The conductive layer E1 may include one selected from among molybdenum (Mo), aluminum (Al), chromium (Cr), gold (Au), titanium (Ti), nickel (Ni), neodymium (Nd), and copper (Cu).

The first semiconductor layer SEM1 may be arranged on the conductive layer E1. The first semiconductor layer SEM1 may be formed of a semiconductor material layer, such as gallium nitride (GaN), doped with a first conductive dopant, such as magnesium (Mg), zinc (Zn), calcium (Ca), strontium (Sr), barium (Ba), and/or the like.

The active layer MQW may be arranged on the first semiconductor layer SEM1. The active layer MQW may be to emit light by combining electron-hole pairs according to an electrical signal applied through the first semiconductor layer SEM1 and the second semiconductor layer SEM2.

The active layer MQW may include a material having a single or multi-quantum well structure. When the active layer MQW includes a material having a multi-quantum well structure, it may have a structure in which a plurality of well layers and barrier layers are alternately stacked. In one or more embodiments, the well layer may be formed of indium gallium nitride (InGaN), and the barrier layer may be formed of gallium nitride (GaN) or aluminum gallium nitride (AlGaN), but embodiments of the present disclosure are not limited thereto.

In one or more embodiments, the active layer MQW may have a structure in which semiconductor materials having a high band gap energy and semiconductor materials having a low band gap energy are alternately stacked with each other, may include other Group three (III) to five (V) semiconductor materials according to the wavelength range of emitted light.

In one or more embodiments, if (e.g., when) the active layer MQW includes InGaN, the color of the emitted light may vary depending on the content (e.g., amount) of indium (In). For example, as the content (e.g., amount) of indium (In) increases, the wavelength band of light emitted by the active layer may shift to the red wavelength band, and as the content (e.g., amount) of indium (In) decreases, the wavelength band of light emitted by the active layer may shift to the blue wavelength band. For example, the content (e.g., amount) of indium (In) in the active layer MQW of the light emitting element LE that emits the third light (light in the blue wavelength band) may be approximately (about) 10 wt% to (about) 20 wt%.

The second semiconductor layer SEM2 may be arranged on the active layer MQW. The second semiconductor layer SEM2 may be a semiconductor material layer, for example gallium nitride (GaN), doped with a second conductive dopant such as silicon (Si), germanium (Ge), tin (Sn), and/or the like.

The third semiconductor layer SEM3 may be arranged on the second semiconductor layer SEM2.

The third semiconductor layer SEM3 may be a semiconductor material layer in which an N-type (kind) dopant is lower than a set or predetermined threshold value/concentration and may be referred to as an undoped semiconductor layer. For example, the third semiconductor layer SEM3 may be indium aluminum gallium nitride (InAlGaN), gallium nitride (GaN), aluminum gallium nitride (AlGaN), indium gallium nitride (InGaN), aluminum nitride (AlN), or indium nitride (InN), where the N-type (kind) dopant is lower than a set or predetermined threshold value/concentration.

A top surface of the third semiconductor layer SEM3 may have light extraction patterns LEP.

The light extraction patterns LEP may be patterns for increasing the efficiency of light emitted from the top surface of the light emitting element LE. The light extraction patterns LEP may be concave patterns formed in a hemisphere or a semi-ellipse. The light extraction patterns LEP may be concave patterns having a cross-sectional shape of a semicircle or a semi-ellipse.

In one or more embodiments, an electron blocking layer may be arranged between the first semiconductor layer SEM1 and the active layer MQW. The electron blocking layer may be a layer to suppress or prevent or reduce too many electrons from flowing into the active layer MQW. For example, the electron blocking layer may be aluminum gallium nitride (AlGaN) or P-type (kind) aluminum gallium nitride (AlGaN) doped with p-type (kind) magnesium (Mg). In one or more embodiments, the electronic blocking layer may not be provided.

In one or more embodiments, a superlattice layer may be arranged between the active layer MQW and the second semiconductor layer SEM2. The superlattice layer may be a layer for relieving stress between the second semiconductor layer SEM2 and the active layer MQW. For example, the superlattice layer may be aluminum gallium nitride (AlGaN) or P-type (kind) aluminum gallium nitride (AlGaN) doped with p-type (kind) magnesium (Mg). In one or more embodiments, the superlattice layer may not be provided.

The protective film INS may be a film for protecting the light emitting element LE. The protective film INS may cover at least a portion of the outer peripheral surfaces of the plurality of semiconductor layers SEM1, MQW, SEM2, and SEM3 of the light emitting element LE. For example, the protective film INS may cover the entire outer peripheral surfaces except for the top surfaces of the plurality of semiconductor layers SEM1, MQW, SEM2, and SEM3. The protective film INS may be arranged on a bottom surface and side surfaces of the conductive layer E1 and on side surfaces of the plurality of semiconductor layers SEM1, MQW, SEM2, and SEM3. The protective film INS may be formed of an inorganic film, such as silicon nitride (SiNₓ), silicon oxide nitride (SiON), silicon oxide (SiOₓ), titanium oxide (TiOₓ), or aluminum oxide (AlOₓ). The protective film INS may be arranged from one end to the other end of the side surface of the light emitting element LE but may be arranged to be spaced and/or apart from one end due to a process error.

A hole LEH may be formed to penetrate the conductive layer E1, the first semiconductor layer SEM1, and the active layer MQW of the light emitting element LE to expose the second semiconductor layer SEM2. In one or more embodiments, the hole LEH may have a rectangular planar shape, but the embodiments of the present disclosure are not limited thereto. For example, in one or more embodiments, the hole LEH may have a polygonal planar shape, a circle shape, an oval shape, or a square shape.

In addition, the protective film INS may be arranged on a sidewall of the conductive layer E1, a sidewall of the first semiconductor layer SEM1, and a sidewall of the active layer MQW, each exposed in the hole LEH. The protective film INS may not cover the second semiconductor layer SEM2 in the hole LEH. Therefore, the second semiconductor layer SEM2 may be exposed without being covered by the protective film INS.

The first contact electrode CTE1 may be arranged on one surface of the conductive layer E1. The first contact electrode CTE1 may be arranged on a bottom surface of the conductive layer E1 that is exposed and not covered by the protective film INS. Therefore, the first contact electrode CTE1 may be electrically connected to the conductive layer E1.

The second contact electrode CTE2 may be arranged on one surface of the conductive layer E1. The second contact electrode CTE2 may be arranged on the protective film INS arranged in the hole LEH and the second semiconductor layer SEM2 exposed in the hole LEH without being covered by the protective film INS. Therefore, the second contact electrode CTE2 may be electrically connected to the second semiconductor layer SEM2 in the hole LEH.

The first contact electrode CTE1 and the second contact electrode CTE2 may each independently include one selected from among molybdenum (Mo), aluminum (Al), chromium (Cr), gold (Au), titanium (Ti), nickel (Ni), neodymium (Nd), and copper (Cu). For example, in one or more embodiments, the first contact electrode CTE1 and the second contact electrode CTE2 may be formed as a two-layer structure of chromium (Cr) and gold (Au), a three-layer structure of titanium (Ti), aluminum (Al), and titanium (Ti), or a three-layer structure of indium tin oxide (ITO), silver (Ag), and indium tin oxide (ITO) to increase reflectivity.

The connection electrodes BE1 and BE2 bond the light emitting element LE to the pixel electrode layer and electrically connect the light emitting element LE to the pixel electrode layer. For example, the connection electrodes BE1 and BE2 may include a first connection electrode BE1 and a second connection electrode BE2. The first connection electrode BE1 connects the first contact electrode CTE1 of the light emitting element LE and the pixel electrodes PXE1, PXE2, and PXE3. The first connection electrode BE1 may be arranged between the first contact electrode CTE1 of the light emitting element LE and the pixel electrode PXE2. Accordingly, the first connection electrode BE1 may connect the conductive layer E1 of the light emitting element LE and the pixel electrodes PXE1, PXE2, and PXE3. Furthermore, the second connection electrode BE2 connects the second contact electrode CTE2 of the light emitting element LE and the common electrodes CE1, CE2, and CE3. The second connection electrode BE2 may be arranged on the second contact electrode CTE2 arranged on the side surface of the plurality of semiconductor layers SEM1, MQW, SEM2, and SEM3, and may be arranged on the common electrode CE1, CE2, and CE3. Accordingly, the second connection electrode BE2 may connect the second semiconductor layer SEM2 of the light emitting element LE and the common electrodes CE1, CE2, and CE3.

The first connection electrode BE1 and the second connection electrode BE2 may be spaced apart from the top surface of the semiconductor stack STC in the third direction DR3. The first connection electrode BE1 and the second connection electrode BE2 may be formed lower than at least one end of the first contact electrode CTE1 and the second contact electrode CTE2. For example, the distance between the first connection electrode BE1 and the top surfaces of the plurality of semiconductor layers SEM1, MQW, SEM2, and SEM3 may be greater than the distance between the first contact electrode CTE1 and the top surfaces of the plurality of semiconductor layers SEM1, MQW, SEM2, and SEM3, and the distance between the second connection electrode BE2 and the top surfaces of the plurality of semiconductor layers SEM1, MQW, SEM2, and SEM3 may be greater than the distance between the second contact electrode CTE2 and the top surfaces of the plurality of semiconductor layers SEM1, MQW, SEM2, and SEM3.

The first connection electrode BE1 and the second connection electrode BE2 may include at least one of gold (Au), copper (Cu), tin (Sn), silver (Ag), aluminum (Al), and titanium (Ti). For example, the first connection electrode BE1 and the second connection electrode BE2 may include a 9:1 alloy, an 8:2 alloy, or a 7:3 alloy of gold and tin.

The first connection electrode BE1 and the second connection electrode BE2 may include a eutectic metal or a bonding metal.

In one or more embodiments, the light emitting elements LE are bonded to the pixel electrode layer by the connection electrodes BE1 and BE2, but the present disclosure is not limited thereto. For example, an adhesive layer may be arranged between the light emitting elements LE and the pixel electrode layer. When the adhesive layer is arranged, the contact electrodes CTE1 and CTE2 may extend to the side surfaces of the plurality of light emitting elements LE, thereby connecting the contact electrodes CTE1 and CTE2 and the pixel electrode layer by a separate connection electrode. The adhesive layer may be an insulating material having adhesive properties and may serve to fix the light emitting elements attached to the adhesive layer.

According to one or more embodiments, the structural configuration of the connection electrodes BE1 and BE2 not only ensures robust electrical connectivity between the light-emitting elements LE and the pixel electrode layer but also contributes to mechanical stability during thermal cycling and operation. The utilization of eutectic or bonding metals, such as Au-Sn alloys, facilitates reliable bonding with low contact resistance. Furthermore, the optional inclusion of an adhesive layer provides additional mechanical support and alignment precision, particularly in high-resolution display applications. This configuration enhances the overall durability and performance of the display device, supporting efficient light emission and consistent electrical operation across the panel.

A first organic layer 190 may be arranged to cover a portion of the side surface of each of the plurality of light emitting elements LE. The first organic layer 190 may also be referred to as a via layer. Further, the first organic layer 190 may be arranged to cover the pixel electrode layer. The top surface of each of the plurality of light emitting elements LE may be exposed without being covered by the first organic layer 190.

A passivation layer PSV (e.g., may also refer to a first passivation layer PSV1 (see FIG. 7)) may entirely cover the light emitting elements LE and the first organic layer 190. The passivation layer PSV may also be referred to as a protective layer. The passivation layer PSV may protect components arranged under the passivation layer PSV. In one or more embodiments, the passivation layer PSV may not be arranged on the top surface of the light emitting elements LE.

The passivation layer PSV may include an inorganic insulating layer including an inorganic material and/or an organic insulating layer including an organic material. The inorganic insulating layer may include, for example, at least one selected from among metal oxides such as silicon oxide, silicon nitride, silicon oxynitride, and aluminum oxide. The organic insulating layer may include, for example, at least one selected from among an acrylic resin, an epoxy resin, a phenol resin, a polyamide resin, a polyimide resin, an unsaturated polyester resin, a poly-phenylene ether resin, a poly-phenylene sulfide resin, and a benzocyclobutene-based resin.

A light blocking layer BM, a first light conversion layer QDL1, a second light conversion layer QDL2, and a light transmission layer TPL may be arranged on the first passivation layer PSV1 (i.e., passivation layer PSV). The first light conversion layer QDL1, the second light conversion layer QDL2, and the light transmission layer TPL may be referred to as light extraction structures.

The light blocking layer BM may be arranged between the first light conversion layer QDL1, the second light conversion layer QDL2, and the light transmission layer TPL. Accordingly, the light blocking layer BM may surround the first light conversion layer QDL1, the second light conversion layer QDL2, and the light transmission layer TPL. The light blocking layer BM may be configured to include a light blocking material, thereby preventing or reducing light mixing between adjacent sub-pixels. In one or more embodiments, the light blocking layer BM may include an organic material. For example, the light blocking layer BM may include an organic insulating material such as an acryl resin, an epoxy resin, a phenol resin, a polyamide resin, a polyimide resin, and/or the like.

A capping layer CAP may entirely cover the light extraction structure and the passivation layer PSV. The capping layer CAP may protect components under the capping layer CAP, such as the light emitting element LE, from external moisture and humidity. The capping layer CAP may include at least one of a silicon nitride, a silicon oxide, a silicon oxynitride, or a metal oxide such as an aluminum oxide. However, the material of the capping layer CAP is not limited thereto. In one or more embodiments, the capping layer CAP may not be provided.

An upper end of the light blocking layer BM may be positioned lower than an upper end of the light extraction structure. The light blocking layer BM may not cover a side surface adjacent to a top surface of the light extraction structure.

If (e.g., when) the light blocking layer BM is formed higher than the light extraction structure, it may be to absorb some of the light emitted from the light emitting element LE, so that the light extraction efficiency may be reduced.

A reflective layer RF is interposed between the light blocking layer BM and the light extraction structure. The reflective layer RF may surround at least a side surface of the light extraction structure. For example, in one or more embodiments, the reflective layer RF may surround at least a portion of the side surface of the light extraction structure. The reflective layer RF may include a material suitable for reflecting light. The reflective layer RF may include at least one selected from among aluminum (Al), silver (Ag), magnesium (Mg), platinum (Pt), palladium (Pd), gold (Au), nickel (Ni), neodymium (Nd), iridium (Ir), chromium (Cr), titanium (Ti), and an alloy of two or more materials selected therefrom. However, the embodiments of the present disclosure are not limited thereto. The light extraction structure and the reflective layer RF may serve to improve the light emission efficiency of light generated from the light emitting element LE. For example, in one or more embodiments, the light extraction structure may include a negative photoresist material. Accordingly, the light extraction structure may be formed to have a side surface including a reverse tapered slope. The side surface of the light extraction structure may include a reverse tapered slope. For example, as shown in FIG. 7, the first light conversion layer QDL1, which is a light extraction structure, may have a shape substantially identical to (or similar to) a trapezoidal shape in which the length of an upper side is longer than the length of a lower side in a cross-section. The light extraction structures may be arranged to overlap the corresponding light emitting elements. The light extraction structures may surround at least a portion of a side surface adjacent to the top surface of the light emitting element. For example, the first light conversion layer QDL1 may surround at least a portion of a side surface adjacent to the top surface of the first light emitting element LE1. The second light conversion layer QDL2 may surround at least a portion of a side surface adjacent to the top surface of the second light emitting element LE2. The light transmission layer TPL may surround at least a portion of a side surface adjacent to the top surface of the third light emitting element LE3.

In one or more embodiments, an upper edge of each of the light extraction structures may have a rounded shape. In this regard, the side surface between a bottom surface and the upper edge of the light extraction structure may be a reverse tapered slope.

The reflective layer RF around (e.g., surrounding) the side surface of the light extraction structure, for example, the first light conversion layer QDL1, may also have a reverse taper shape corresponding to the shape of the side surface of the light extraction structure (e.g., first light conversion layer QDL1). However, an upper end of the reflective layer RF may be arranged lower than the upper end of the light extraction structure (e.g., first light conversion layer QDL1). The top surface and the side surface adjacent to the top surface of the light extraction structures may not be covered by the reflective layer RF. The upper end of the reflective layer RF may be arranged at the same height or lower than the upper end of the light blocking layer BM.

A second passivation layer PSV2 may cover the reflective layer RF. Therefore, the second passivation layer PSV2 may surround the side surface of the light extraction structure (e.g., first light conversion layer QDL1) on the outside of the reflective layer RF. The side surface shape of the second passivation layer PSV2 may also have a reverse taper shape corresponding to the shape of the side surface of the light extraction structure (e.g., first light conversion layer QDL1).

The side of the light blocking layer BM and the side of the reflective layer RF may be aligned (e.g., parallel) with each other.

The first light conversion layer QDL1 may convert a portion of the third light (light in the blue wavelength band) incident from the light emitting element LE into first light (light in the red wavelength band). The first light conversion layer QDL1 may include a first base resin BRS1 and a first wavelength conversion particle WCP1. The first base resin BRS1 may include a light-transmitting organic material. The first wavelength conversion particle WCP1 may convert a portion of the third light (light in the blue wavelength band) incident from the light emitting element LE into the first light (light in the red wavelength band).

The second light conversion layer QDL2 may convert a portion of the third light (light in the blue wavelength band) incident from the light emitting element LE into second light (light in the green wavelength band). The second light conversion layer QDL2 may include a second base resin BRS2 and a second wavelength conversion particle WCP2. The second base resin BRS2 may include a light-transmitting organic material. The second wavelength conversion particle WCP2 may convert a portion of the third light (light in the blue wavelength band) incident from the light emitting element LE into the second light (light in the green wavelength band).

The light transmission layer TPL may include a light-transmitting organic material.

For example, the first base resin BRS1, the second base resin BRS2, and the light transmission layer TPL may include an epoxy-based resin, an acrylic-based resin, a cardo-based resin, or an imide-based resin. The first and second wavelength conversion particles WCP1 and WCP2 may each independently be quantum dots (QD), quantum rods, fluorescent materials, or phosphorescent materials. In one or more embodiments, each of the first light conversion layer QDL1, the second light conversion layer QDL2, and the light transmission layer TPL may further include a scattering particle.

A second organic layer 210 may be arranged on the light extraction structure and the light blocking layer BM.

The second organic layer 210 may also be referred to as a planarization layer. The second organic layer 210 may include a same material as the first organic layer 190, but the embodiments of the present disclosure are not limited thereto. The second organic layer 210, a high refractive index layer HRL, and a multi-lens layer MLL may be referred to as a light functional layer LFL.

The second organic layer 210 may have a groove 210-h in an area overlapping the light blocking layer BM in the third direction DR3. The high refractive index layer HRL may be formed in the groove 210-h of the second organic layer 210. The high refractive index layer HRL may overlap the light blocking layer BM in the third direction DR3 and may not overlap the light emitting element LE. The high refractive index layer HRL may have a higher refractive index than the refractive index of the second organic layer 210. The high refractive index layer HRL may be formed as a connected pattern that surrounds the light emitting element LE and is spaced and/or apart from the light emitting element LE. In one or more embodiments, the high refractive index layer HRL may have a square shape at the edge in the cross section, but embodiments of the present disclosure are not limited thereto, for example, the edge thereof may have a circular shape. The high refractive index layer HRL may change the path of light emitted from the light emitting element LE so that light traveling in a side direction rather than an upward direction (the third direction DR3) travels in the upward direction (the third direction DR3).

The multi-lens layer MLL that overlaps the light extraction structure may be arranged on the second organic layer 210.

The multi-lens layer MLL may include one first type (kind) lens ML1 having a first curvature and a plurality of second type (kind) lenses ML2 each having a second curvature. The first type (kind) lens ML1 and the plurality of second type (kind) lenses ML2 may be provided convexly toward the front. The first curvature and the second curvature may be different. The first curvature may be smaller than the second curvature. For example, the first type (kind) lens ML1 may be flatter than the second type (kind) lens ML1. The first type (kind) lens ML1 may be circular, elliptical, or rectangular, but embodiments of the present disclosure are not limited thereto. The second type (kind) lens may be circular, elliptical, or rectangular. The shape of the first type (kind) lens and the shape of the second type (kind) lens may be the same, but embodiments of the present disclosure are not limited thereto. For example, the first type (kind) lens may be rectangular, and the second type (kind) lens may be circular.

The first type (kind) lens ML1 may be arranged at a center of the multi-lens layer MLL. The first type (kind) lens ML1 may overlap the light emitting element LE in the third direction DR3 and may not overlap the light blocking layer BM. the plurality of second type (kind) lenses ML2 may be arranged around the first type (kind) lens ML1. On a plane, the plurality of second type (kind) lenses ML2 may be arranged to surround the first type (kind) lens ML1. The plurality of second type (kind) lenses ML2 may overlap a portion of the light blocking layer BM in the third direction DR3 and may not overlap the light emitting element LE.

A width W1 of the first type (kind) lens ML1 may be wider than a width W2 of the second type (kind) lens ML2. A height h1 of the first type (kind) lens ML1 may be equal to or lower than a height h2 of the second type (kind) lens ML2. The multi-lens layer MLL may be made of an organic material having a refractive index higher than the refractive index of the second organic layer 210 and equal to or lower than the refractive index of the high refractive index layer HRL.

The first type (kind) lens ML1 and the second type (kind) lens ML2 may change the path of some of the light emitted from the light emitting element LE. The light emitted from the light emitting element LE may be to transmit through the light extraction structure, and some of the transmitted light may be incident on the multi-lens layer MLL. The multi-lens layer MLL may collect the incident light and transmit it to the outside.

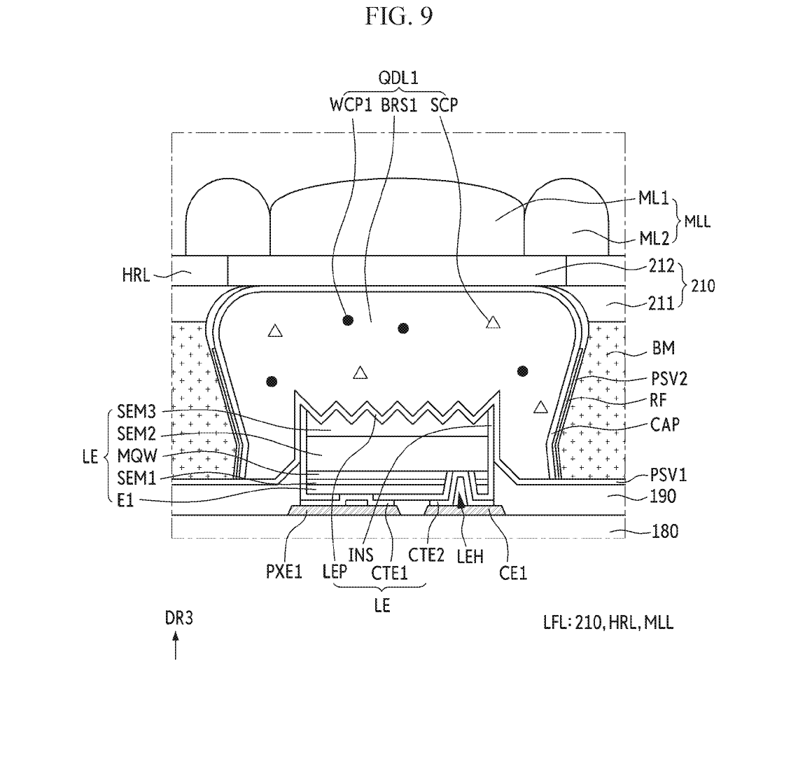

FIG. 9 is a cross-sectional view illustrating another example of the area A of FIG. 6 in more detail according to one or more embodiments of the present disclosure.

FIG. 9 may differ from the embodiment of FIG. 7 in that the second organic layer 210 includes a second-first organic layer 211 and a second-second organic layer 212. In FIG. 9, descriptions that overlap with the embodiment described with reference to FIG. 7 will not be repeated, and only differences from the embodiment of FIG. 7 will be mainly described.

Referring to FIG. 9, the second-first organic layer 211 may be arranged on the light extraction structure and the light blocking layer BM, and a high refractive index layer HRL and the second-second organic layer 212 may be arranged on the light extraction structure and the second-first organic layer 211. The second-first organic layer 211 may serve to flatten (e.g., planarize) a step between the light extraction structure and the light blocking layer BM. Furthermore, the high refractive index layer HRL may be arranged on the second-first organic layer 211 overlapping the light blocking layer BM in the third direction DR3, and the second-second organic layer 212 may play a role in flattening (e.g., planarizing) a step formed by the high refractive index layer HRL. The second-first organic layer 211 and the second-second organic layer 212 may include a same material as the first organic layer 190, but embodiments of the present disclosure are not limited thereto.

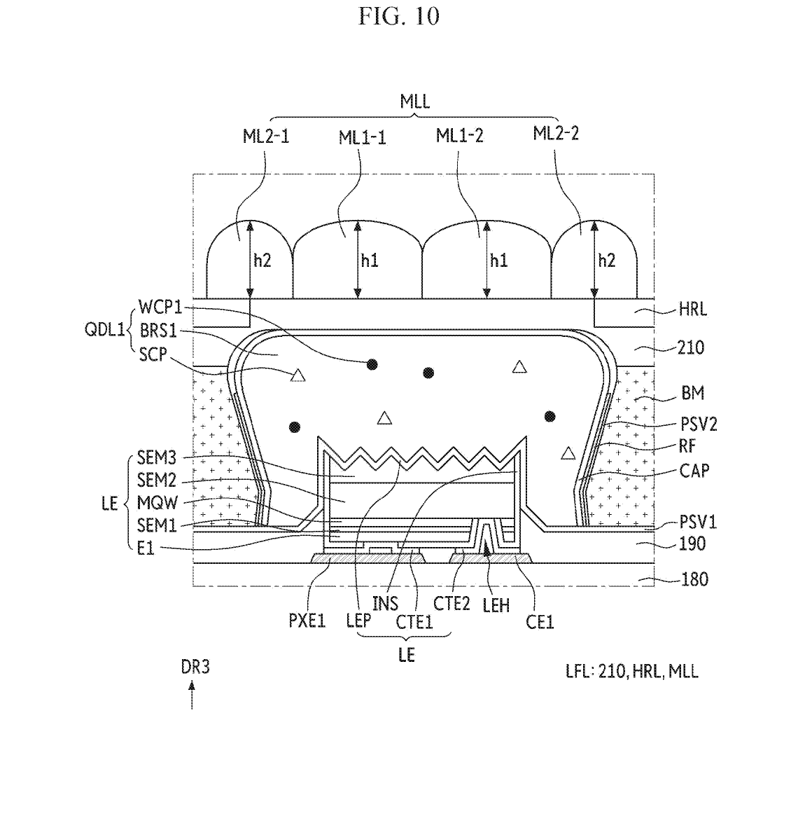

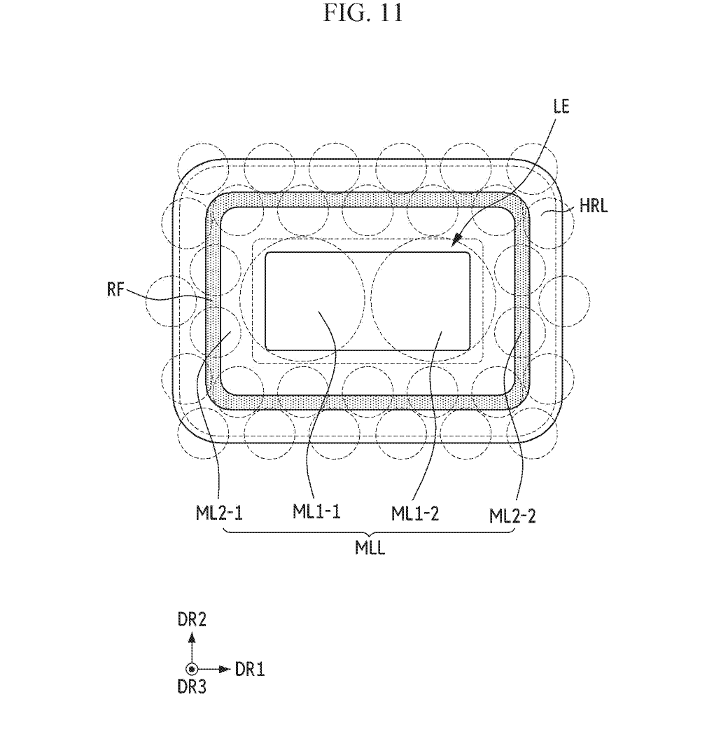

FIG. 10 is a cross-sectional view illustrating an example of the area A of FIG. 6 in more detail according to one or more embodiments of the present disclosure. FIG. 11 is a plan view illustrating a relationship between the multi-lens layer and the high refractive index layer of FIG. 10 and surrounding components according to one or more embodiments.

Referring to FIG. 10 and FIG. 11, the embodiment may be different from the embodiment of FIG. 7 in that a plurality of first type (kind) lenses ML1 are used. In FIG. 10 and FIG. 11, descriptions that overlap with the embodiment described with reference to FIG. 7 will not be repeated, and only differences from the embodiment of FIG. 7 will be mainly described.

Referring to FIG. 10 and FIG. 11, a first-first type (kind) lens ML first-first and a first-second lens ML1-2 may be arranged as the first type (kind) lens ML1.

The multi-lens layer MLL may include a first-first lens ML1-1 having a first curvature, a first-second type (kind) lens ML1-2, and a plurality of second type (kind) lenses ML2-1 and ML2-2 each having a second curvature. The first-first type (kind) lens ML1-1, the first-second type (kind) lens ML1-2, and the plurality of second type (kind) lenses ML2-1 and ML2-2 may be provided to be convex toward the front. The first curvature and the second curvature may be different. The first curvature may be smaller than the second curvature. For example, the first-first type (kind) lens ML1-1 and the first-second type (kind) lens ML1-2 may be flatter than the second type (kind) lens ML2-1 or ML2-2.

The first-first type (kind) lens ML1-1 and the first-second type (kind) lens ML1-2 may be arranged at the center of the multi-lens layer MLL. The first-first type (kind) lens ML1-1 and the first-second type (kind) lens ML1-2 may overlap the light emitting element LE in the third direction DR3 and may not overlap the light blocking layer BM. The plurality of second type (kind) lenses ML2-1 and ML2-2 may be arranged around the first-first type (kind) lens ML1-1 and the first-second type (kind) lens ML1-2. On a plane, the plurality of second type (kind) lenses ML2-1 and ML2-2 may be arranged to surround the first-first type (kind) lens ML1-1 and the first-second type (kind) lens ML1-2. The plurality of second type (kind) lenses ML2-1 and ML2-2 may overlap a portion of the light blocking layer BM in the third direction DR3 and may not overlap the light emitting element LE.

The first-first type (kind) lens ML1-1 and the first-second type (kind) lens ML1-2 may have a same width W1. The second type (kind) lenses ML2-1 and ML2-2 may each have a narrower width W2 than the width W1. The first-first type (kind) lens ML1-1 and the first-second type (kind) lens ML1-2 may have a same height h1. The second type (kind) lenses ML2-1 and ML2-2 may each have a height h2 that is equal to or higher than the height h1.

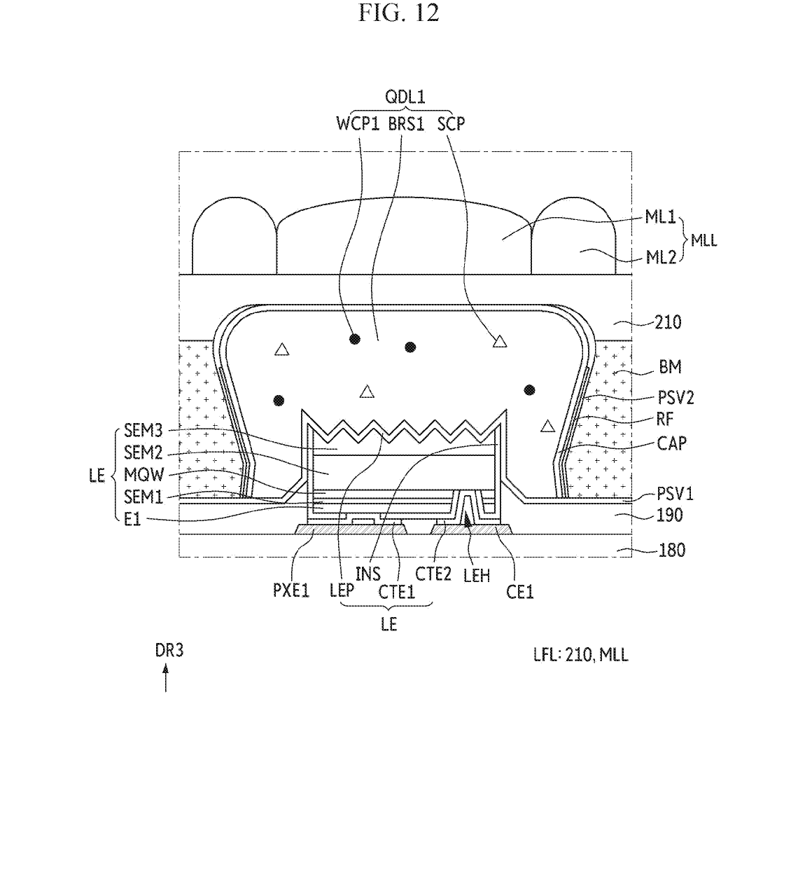

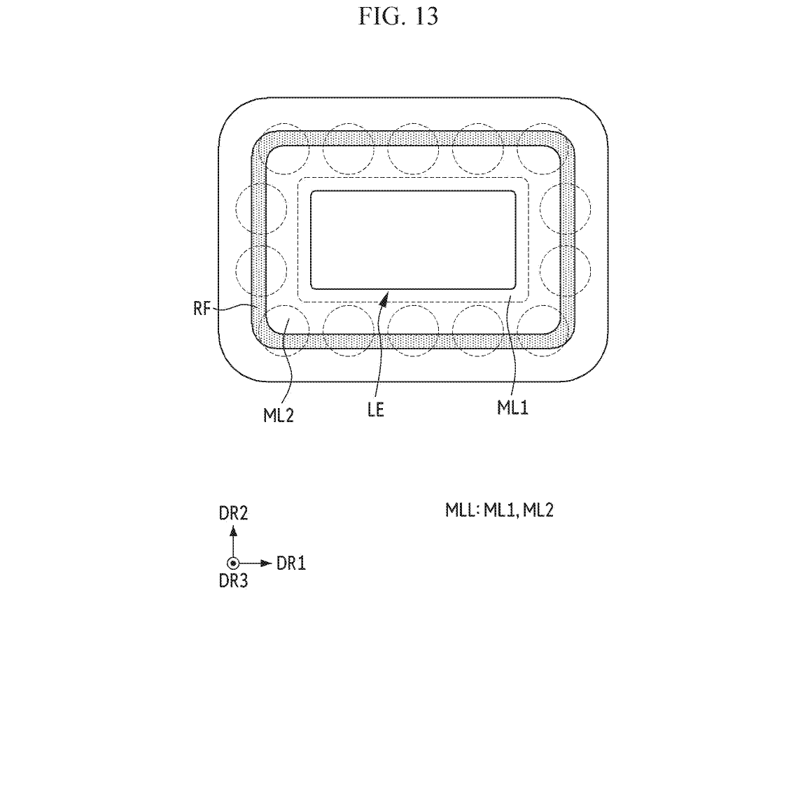

FIG. 12 is a cross-sectional view illustrating an example of the area A of FIG. 6 in more detail according to one or more embodiments of the present disclosure. FIG. 13 is a plan view illustrating a relationship between the multi-lens layer of FIG. 12 and surrounding components according to one or more embodiments.

Referring to FIG. 12 and FIG. 13, the embodiment may differ from that of FIG. 7 in that the high refractive index layer HRL is not provided. In describing FIG. 12 and FIG. 13, descriptions that overlap with the embodiment described with reference to FIG. 7 will not be repeated, and only differences from the embodiment of FIG. 7 will be mainly described.

Referring to FIG. 12 and FIG. 13, a light function layer LFL is arranged on top of the light extraction structure and the light blocking layer BM and includes a second organic layer 210 and a multi-lens layer MLL and does not include a high refractive index layer HRL.

The second organic layer 210 may be referred to as a planarization layer. The second organic layer 210 may include a same material as the first organic layer 190, but embodiments of the present disclosure are not limited thereto.

The multi-lens layer MLL that overlaps the light extraction structure may be arranged on the second organic layer 210.

The multi-lens layer MLL may include one first type (kind) lens ML1 having a first curvature and a plurality of second type (kind) lenses ML2 having a second curvature. The first type (kind) lens ML1 and the plurality of second type (kind) lenses ML2 may be provided convexly toward the front. The first curvature and the second curvature may be different. The first curvature may be smaller than the second curvature. For example, the first type (kind) lens ML1 may be flatter than the second type (kind) lens ML2.

In one or more embodiments, the multi-lens layer MLL may have a plurality of first type (kind) lenses ML1.

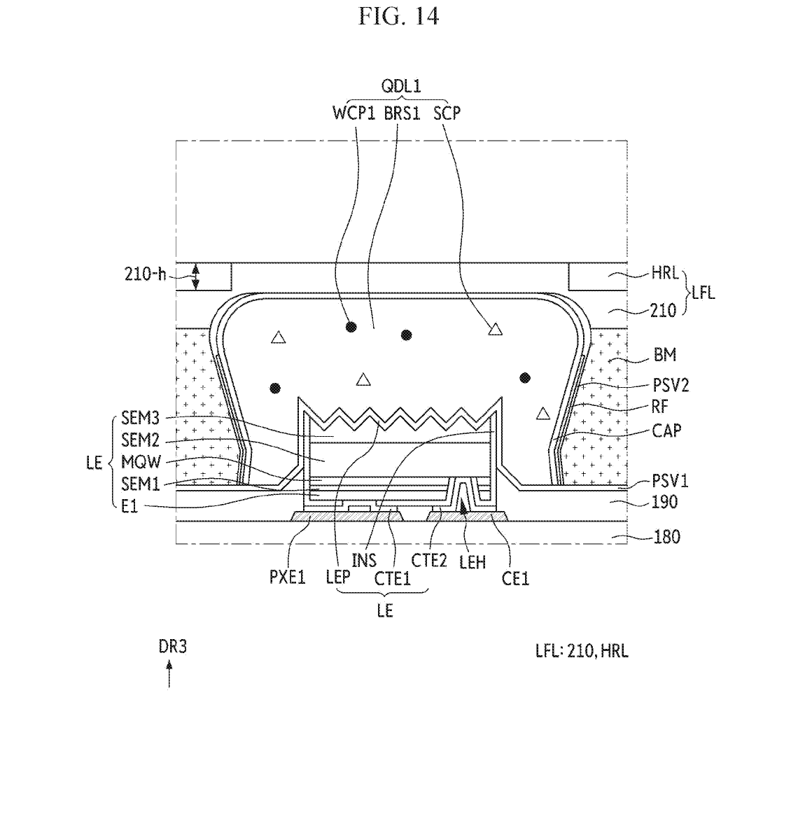

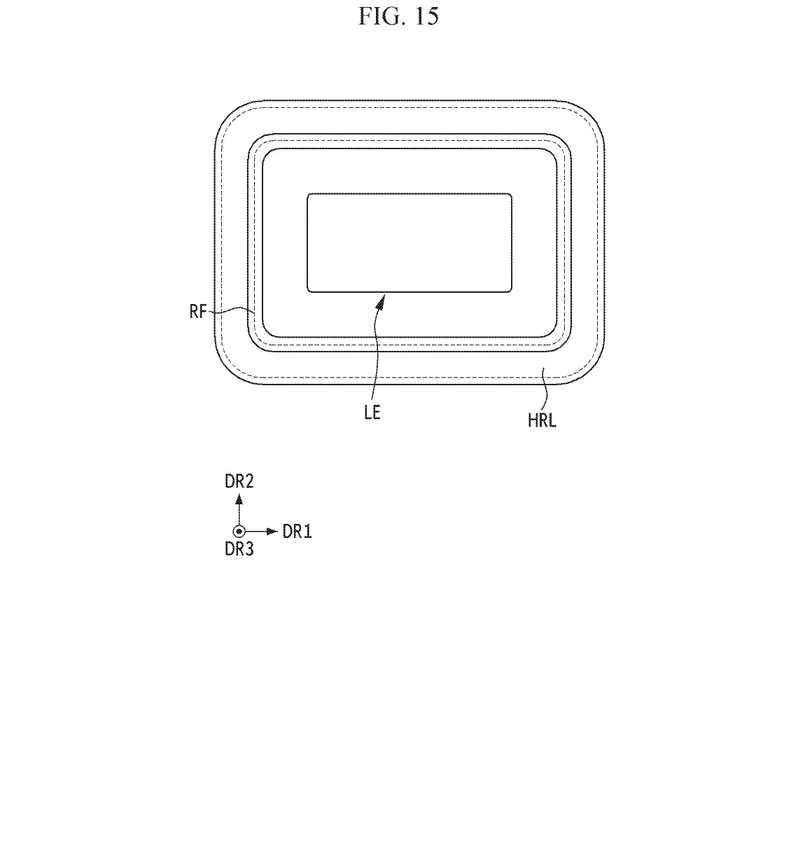

FIG. 14 is a cross-sectional view illustrating an example of the area A of FIG. 6 in more detail according to one or more embodiments of the present disclosure. FIG. 15 is a plan view illustrating a relationship between the high refractive layer of FIG. 14 and surrounding components according to one or more embodiments.

Referring to FIG. 14 and FIG. 15, the embodiment may differ from the embodiment of FIG. 7 in that the multi-lens layer MLL is not provided. In describing FIG. 14 and FIG. 15, the overlapping descriptions with the embodiment described with reference to FIG. 7 will not be repeated, and only differences from the embodiment of FIG. 7 will be mainly described.

Referring to FIG. 14 and FIG. 15, the light function layer LFL is arranged on the light extraction structure and the light blocking layer BM and includes the second organic layer 210 and the high refractive index layer HRL and does not include the multi-lens layer MLL.

The second organic layer 210 may have a groove 210-h in an area overlapping the light blocking layer BM in the third direction DR3. The high refractive index layer HRL may be formed in the groove 210-h of the second organic layer 210. The high refractive index layer HRL may overlap the light blocking layer BM in the third direction DR3 and may not overlap the light emitting element LE. The high refractive index layer HRL may have a higher refractive index than the refractive index of the second organic layer 210.

The high refractive index layer HRL may be formed as a connected pattern that surrounds the light emitting element LE and is spaced and/or apart from the light emitting element LE. In one or more embodiments, the high refractive index layer HRL may have a square shape at the edge in the cross section, but embodiments of the present disclosure are not limited thereto, for example, in one or more embodiments, the edge may have a circular shape. The high refractive index layer HRL may change the path of light emitted from the light emitting element LE so that light traveling in the side direction rather than the upward direction (the third direction DR3) travels in the upward direction (the third direction DR3).

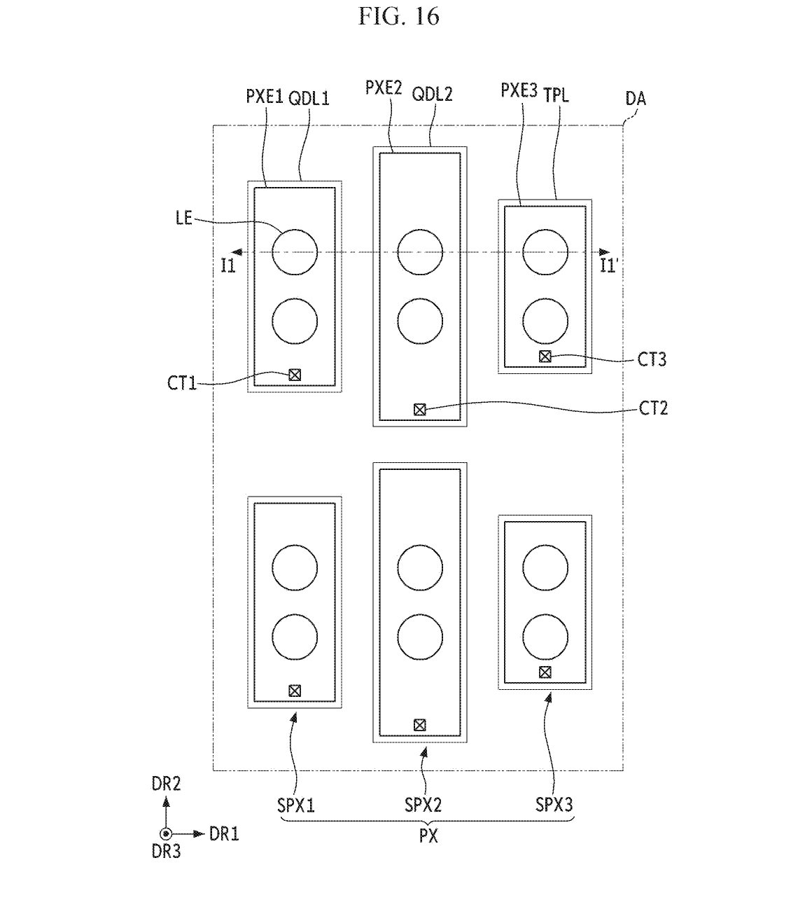

FIG. 16 is a layout diagram illustrating pixels of a display area according to one or more embodiments of the present disclosure.

The embodiment of FIG. 16 differs from the embodiment of FIG. 5 in that the light emitting elements LE overlap the pixel electrodes PXE1, PXE2, and PXE3 in each of the first sub-pixel SPX1, the second sub-pixel SPX2, and the third sub-pixel SPX3. In describing FIG. 16, the description overlapping with the embodiment of FIG. 5 is not repeated for conciseness.

Referring to FIG. 16, the first sub-pixel SPX1 includes a first pixel electrode PXE1, a plurality of light emitting elements LE, and a first light conversion layer QDL1. The second sub-pixel SPX2 includes a second pixel electrode PXE2, a plurality of light emitting elements LE, and a second light conversion layer QDL2. The third sub-pixel SPX3 includes a third pixel electrode PXE3, a plurality of light emitting elements LE, and a light transmission layer (or third light conversion layer) TPL.

In one or more embodiments, each of the first pixel electrode PXE1, the second pixel electrode PXE2, and the third pixel electrode PXE3 may have a rectangular planar shape having a short side in the first direction DR1 and a long side in the second direction DR2. An area of the first sub-pixel SPX1, an area of the second sub-pixel SPX2, and an area of the third sub-pixel SPX3 may be set according to the light conversion efficiency of the first light conversion layer QDL1 and the light conversion efficiency of the second light conversion layer QDL2. For example, the area of the sub-pixel may be larger if the light conversion efficiency of its light conversion layer is lower.

For example, as shown in FIG. 16, if (e.g., when) the light conversion efficiency of the second light conversion layer QDL2 is lower than the light conversion efficiency of the first light conversion layer QDL1, the area of the second pixel electrode PXE2 may be larger than the area of the first pixel electrode PXE1. Furthermore, because the light transmission layer TPL directly transmits the light of the light emitting element LE, while the first light conversion layer QDL1 needs to convert the light, the area of the first pixel electrode PXE1 may be larger than the area of the third pixel electrode PXE3.

Each of the pixel electrodes PXE1, PXE2, and PXE3 may be electrically connected to at least one transistor through a respective pixel connection hole CT1, CT2, or CT3. For example, each of the pixel electrodes PXE1, PXE2, and PXE3 may be electrically connected to the second electrode of the fourth transistor (ST4 in FIG. 4) and the second electrode of the sixth transistor (ST6 in FIG. 4) of the corresponding sub-pixel.

The plurality of light emitting elements LE may be arranged on each of the pixel electrodes PXE1, PXE2, and PXE3. The same number of light emitting elements LE may be arranged on each of the pixel electrodes PXE1, PXE2, and PXE3. For example, in one or more embodiments, two light emitting elements LE may be arranged on each of the pixel electrodes PXE1, PXE2, and PXE3.

The first light conversion layer QDL1 may completely overlap the plurality of light emitting elements LE of the first pixel electrode PXE1 and the first pixel electrode PXE1. The area of the first light conversion layer QDL1 may be larger than the area of the first pixel electrode PXE1. The first light conversion layer QDL1 may convert or shift the peak wavelength of incident light into light of another specific peak wavelength and emit the light. For example, the first light conversion layer QDL1 may convert or shift third light emitted from the plurality of light emitting elements LE of the first sub-pixel SPX1 into first light.

The second light conversion layer QDL2 may completely overlap with the second pixel electrode PXE2 and the plurality of light emitting elements LE of the second sub-pixel SPX2. The area of the second light conversion layer QDL2 may be larger than the area of the second pixel electrode PXE2. The second light conversion layer QDL2 may convert or shift the peak wavelength of incident light into light of another specific peak wavelength and emit it. For example, the second light conversion layer QDL2 may convert or shift the third light emitted from the plurality of light emitting elements LE of the second sub-pixel SPX2 into second light.

The light transmission layer TPL may completely overlap with the third pixel electrode PXE3 and the plurality of light emitting elements LE of the third sub-pixel SPX3. The light transmission layer TPL may directly transmit the incident light. For example, the light transmission layer TPL may directly transmit the third light emitted from a plurality of light emitting elements LE of the third sub-pixel SPX3.

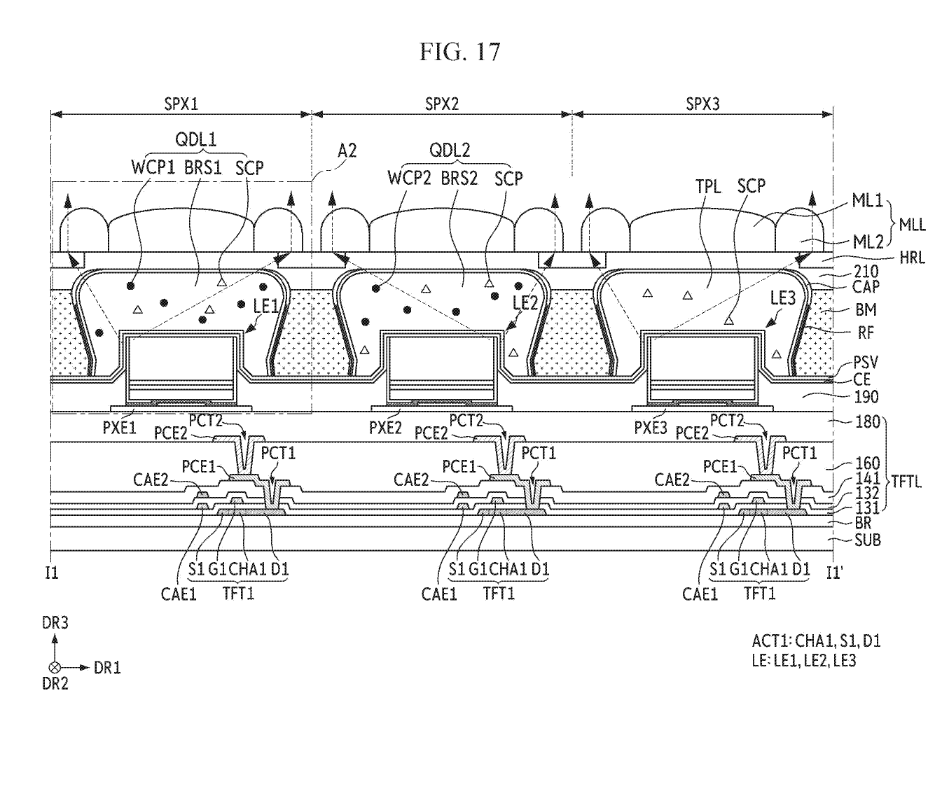

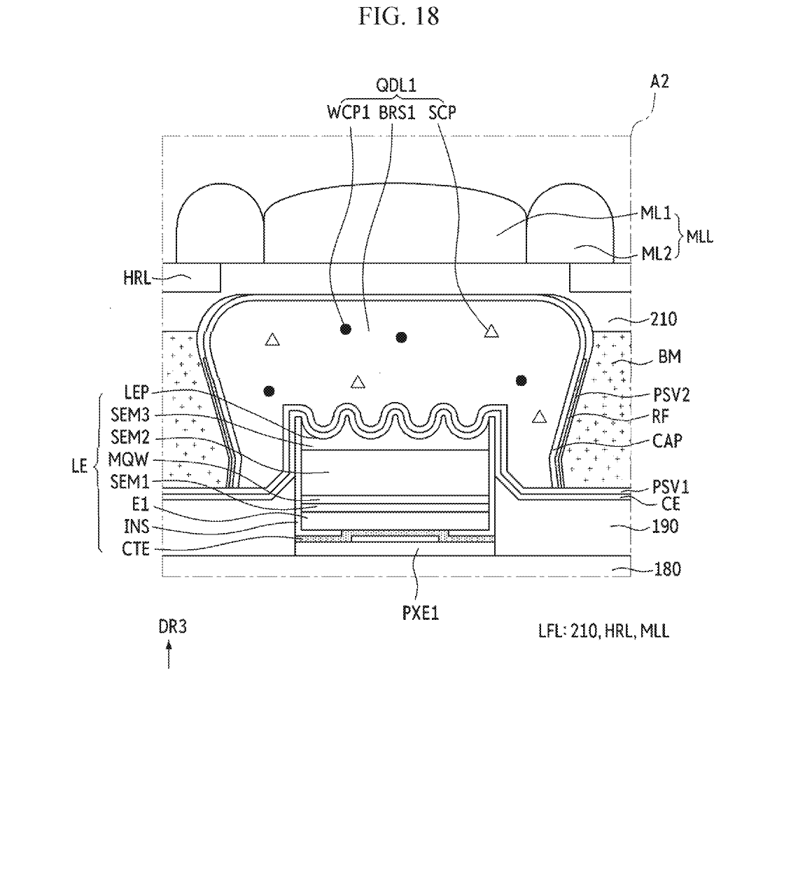

FIG. 17 is a cross-sectional view illustrating one example of a cross-section of a display panel corresponding to the line I1-I1’ of FIG. 16 according to one or more embodiments of the present disclosure. FIG. 18 is a cross-sectional view illustrating an example of the area A2 of FIG. 17 in more detail according to one or more embodiments.

The embodiments of FIGS. 17 and 18 differ from the embodiment of FIG. 6 in that the light emitting elements LE are vertical type (kind) micro LED in which each of the plurality of light emitting elements LE extends in the third direction DR3. The vertical type (kind) micro LED refers to an LED having a structure in which a first semiconductor layer SEM1, an active layer MQW, a second semiconductor layer SEM2, and a third semiconductor layer SEM3 are sequentially arranged in the third direction DR3, which is a vertical direction.

In describing embodiments of FIGS. 17 and 18, descriptions that overlap with those of the embodiments of FIGS. 6 and 7 will not be repeated or will be simplified.

Referring to FIG. 17 and FIG. 18, a pixel electrode layer may be arranged on a second planarization organic film 180. The pixel electrode layer may include a first pixel electrode PXE1, a second pixel electrode PXE2, and a third pixel electrode PXE3.

In one or more embodiments, a reflective film may be arranged on a top surface of each of the first pixel electrode PXE1, the second pixel electrode PXE2, and the third pixel electrode PXE3.

The reflective film may reflect light traveling downward from the light emitting element LE and emit light to a top surface of the light emitting element LE. Therefore, because the loss of light from the light emitting element LE may be reduced, the light efficiency of the light emitting element LE may be increased.

The light emitting elements LE of the first pixel electrode PXE1, the second pixel electrode PXE2, and the third pixel electrode PXE3 are respectively arranged thereon.

Each of the plurality of light emitting elements LE may have a length in the first direction DR1, a length in the second direction DR2, and a length in the third direction DR3 of several to several hundred μm, respectively. For example, each of the plurality of light-emitting elements LE may have a length in the first direction DR1, a length in the second direction DR2, and a length in the third direction DR3 each of approximately (about) 100 μm or less.

The light emitting element LE may include a conductive layer E1, a first semiconductor layer SEM1, an active layer MQW, a second semiconductor layer SEM2, a third semiconductor layer SEM3, a contact electrode CTE, and a protective film INS. The light emitting element LE may have the conductive layer E1, the first semiconductor layer SEM1, the active layer MQW, the second semiconductor layer SEM2, and the third semiconductor layer SEM3 sequentially arranged in the third direction DR3. Light extraction patterns LEP may be formed on a top surface of the light emitting element LE. For example, in one or more embodiments, the light extraction patterns LEP may be formed on the top surface of the light emitting element LE.

The protective film INS may be a film to protect a bottom surface and a side surface of the light emitting element LE. For example, in one or more embodiments, the protective film INS may be arranged on the bottom surface and a side surface of the conductive layer E1, a side surface of the first semiconductor layer SEM1, a side surface of the active layer MQW, and a side surface of the second semiconductor layer SEM2.

The contact electrode CTE may be arranged on the protective film INS. The contact electrode CTE may be arranged between the pixel electrodes PXE1, PXE2, and PXE3 and the protective film INS. Each of the contact electrodes CTE may be connected to the conductive layer E1 that is exposed and not covered by the protective film INS.

In one or more embodiments, a connection electrode may be further arranged between the contact electrode CTE and the pixel electrodes PXE1, PXE2, and PXE3.

A first organic layer 190 may be arranged to cover a portion of the side surface of the plurality of light emitting elements LE. A common electrode CE may be arranged on top surfaces of the first organic layer 190 and the light emitting element LE. The common electrode CE may be electrically connected to the top surface of the light emitting element LE.

A first passivation layer PSV1 may cover the common electrode CE entirely. A light blocking layer BM, a first light conversion layer QDL1, a second light conversion layer QDL2, and a light transmission layer TPL may be arranged on the first passivation layer PSV1.

A second organic layer 210 may be arranged on the light extraction structure and the light blocking layer BM.

A high refractive index layer HRL may be arranged on the second organic layer 210 in an area overlapping the light blocking layer BM in the third direction DR3. Further, a multi-lens layer MLL overlapping the light extraction structure may be arranged on the second organic layer 210.

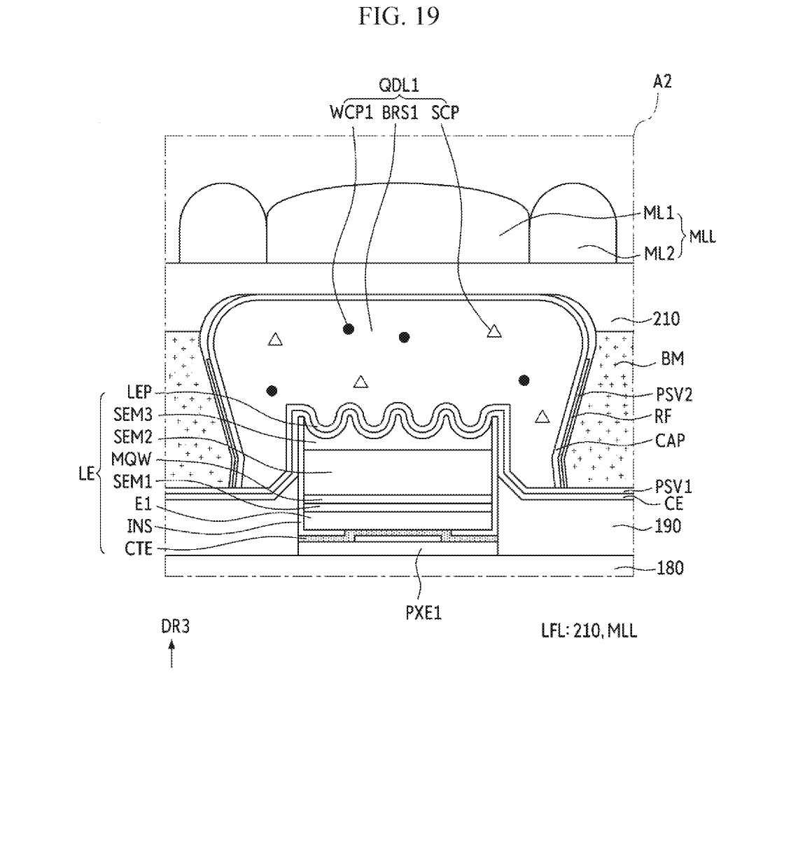

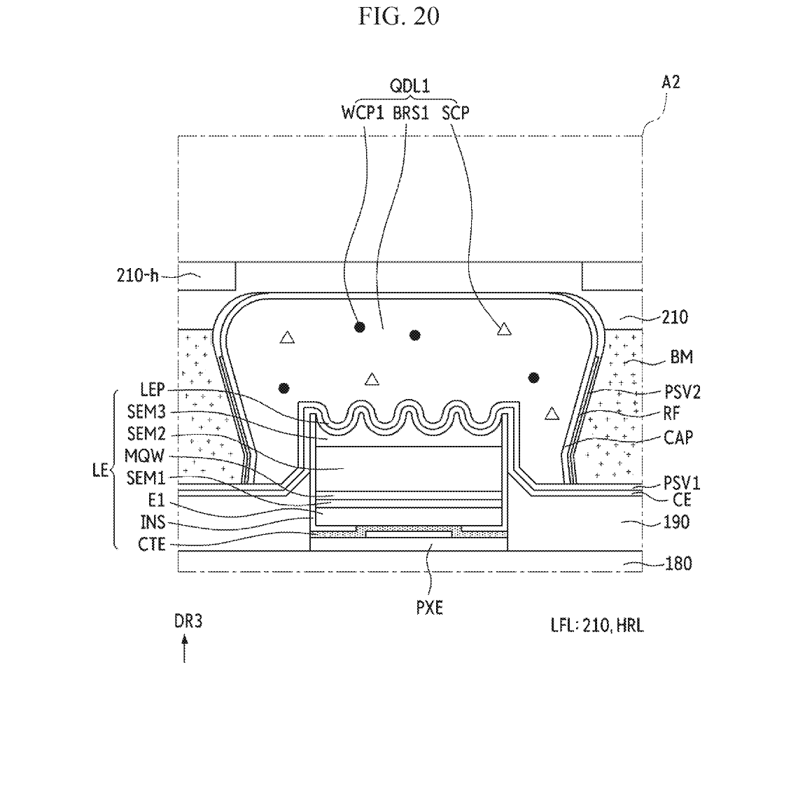

FIG. 19 and FIG. 20 are each a cross-sectional view illustrating an example of a cross-section of a display panel corresponding to the line I1-I1’ of FIG. 16 according to one or more embodiments of the present disclosure. FIG. 19 and FIG. 20 are each a cross-sectional view illustrating one example of the area A2 of FIG. 17 in more detail according to one or more embodiments.

FIG. 19 may be different from the embodiment of FIG. 18 in that the high refractive index layer HRL is not provided. In describing FIG. 19, the overlapping description with the embodiment described with reference to FIGS. 17 and 18 will not be repeated, and the differences from the embodiment of FIGS. 17 and 18 will be mainly described.

Referring to FIG. 19, a light function layer LFL is arranged on top of the light extraction structure and the light blocking layer BM and includes a second organic layer 210 and a multi-lens layer MLL and does not include a high refractive index layer HRL.

The second organic layer 210 may be referred to as a planarization layer. The second organic layer 210 may include a same material as the first organic layer 190, but embodiments of the present disclosure are not limited thereto.

The multi-lens layer MLL that overlaps the light extraction structure may be arranged on the second organic layer 210.

The multi-lens layer MLL may include one first type (kind) lens ML1 having a first curvature and a plurality of second type (kind) lenses ML2 having a second curvature. The first type (kind) lens ML1 and the plurality of second type (kind) lenses ML2 may be provided convexly toward the front. The first curvature and the second curvature may be different. The first curvature may be smaller than the second curvature. For example, the first type (kind) lens ML1 may be flatter than the second type (kind) lens ML1.

In one or more embodiments, the multi-lens layer MLL may have a plurality of first type (kind) lenses ML1.

Referring to FIG. 20, the multi-lens layer MLL may be different from the embodiment of FIG. 17 in that the multi-lens layer MLL is not provided. In describing FIG. 20, the description overlapping with the embodiment described with reference to FIGS. 17 and 18 will not be repeated, and the description will focus on differences from the embodiment of FIGS. 17 and 18.

Referring to FIG. 20, the light function layer LFL is arranged on the light extraction structure and the light blocking layer BM and includes the second organic layer 210 and the high refractive index layer HRL and does not include the multi-lens layer MLL.

The second organic layer 210 may have a groove 210-h in an area overlapping the light blocking layer BM in the third direction DR3. The high refractive index layer HRL may be formed in the groove 210-h of the second organic layer 210. The high refractive index layer HRL may overlap the light blocking layer BM in the third direction DR3 and may not overlap the light emitting element LE. The high refractive index layer HRL may have a higher refractive index than the refractive index of the second organic layer 210.

The high refractive index layer HRL may be formed as a connected pattern that surrounds the light emitting element LE and is spaced and/or apart from the light emitting element LE. In one or more embodiments, the high refractive index layer HRL may have a square shape at the edge in the cross section, but embodiments of the present disclosure are not limited thereto, for example, in one or more embodiments, the edge thereof may have a circular shape. The high refractive index layer HRL may change the path of light emitted from the light emitting element LE so that light traveling in the side direction rather than the upward direction (the third direction DR3) travels in the upward direction (the third direction DR3).

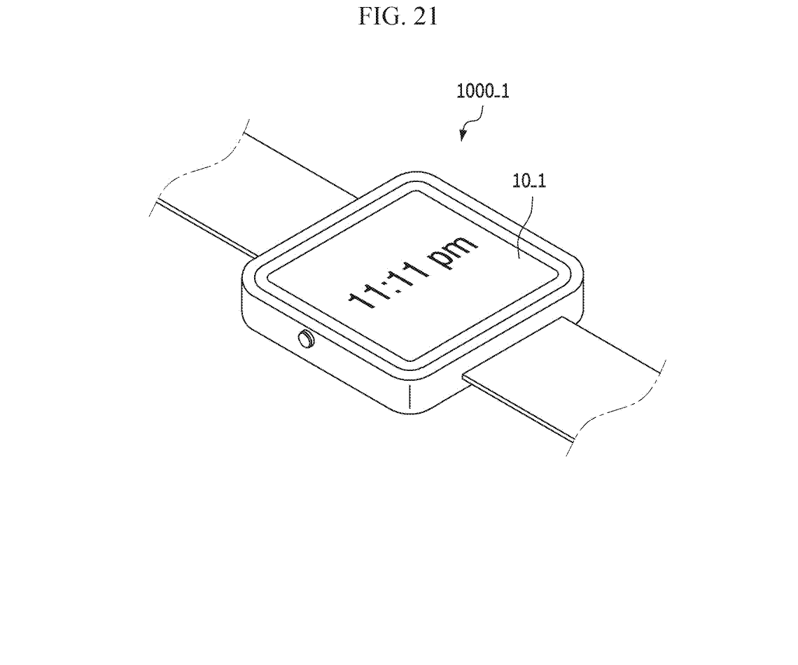

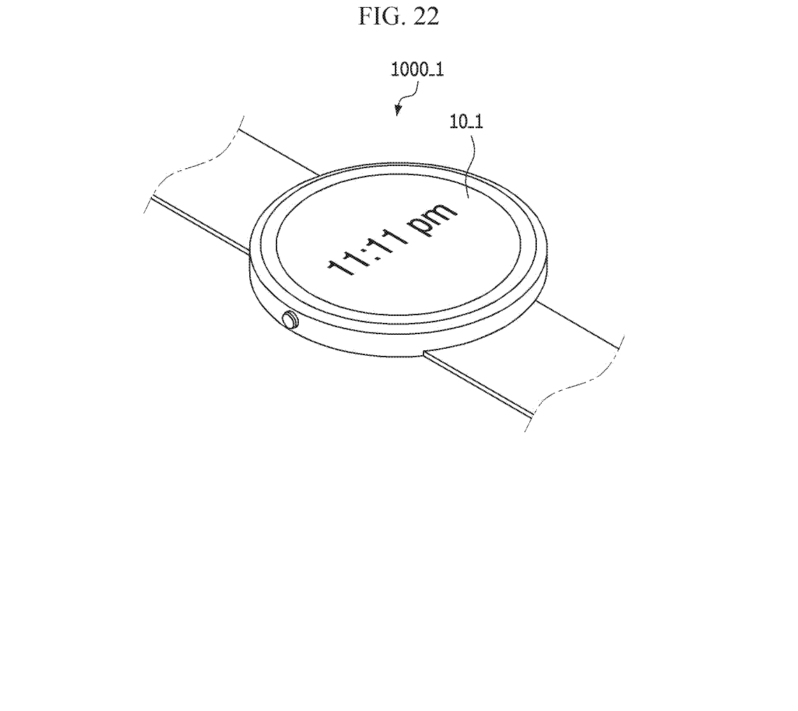

FIG. 21 and FIG. 22 are each an example drawing illustrating a smart watch including a display device according to one or more embodiments of the present disclosure.

Referring to FIG. 21 and FIG. 22, a display device 10_1 according to one or more embodiments may be applied to a smart watch 1000_1, which is one of smart devices.

The flat/planar shape of the display device 10_1 may be a square or a circle, but embodiments of the present disclosure are not limited thereto, for example, the planar shape of the display device 10_1 may be modified in one or more suitable ways, such as an oval.

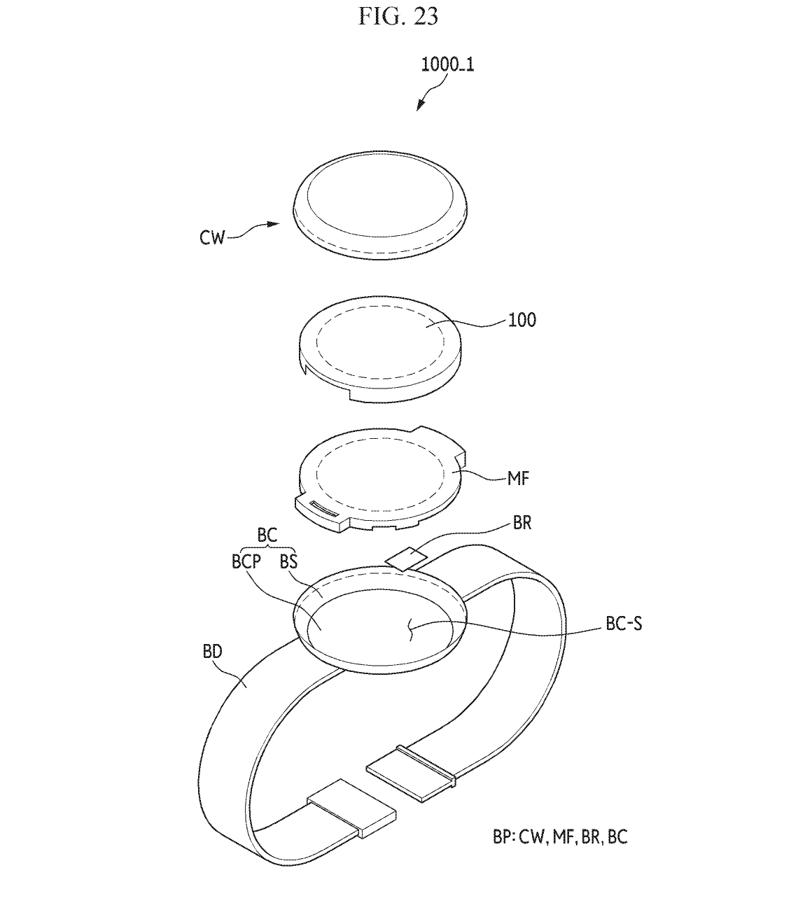

FIG. 23 is an exploded perspective view of a smart watch including a display device according to one or more embodiments of the present disclosure.

Referring to FIG. 23, a smart watch 1000_1 may include a main body unit BP and a wearable portion BD.

The main body unit BP may include a display panel 100 on which an image is displayed, a cover window CW arranged on the display panel 100, a bottom cover BC arranged under the display panel 100, a middle frame MF arranged between the cover window CW and the bottom cover BC, and a battery BR arranged between the middle frame MF and the bottom cover BC. In addition to the battery BR, a main processor controlling the smart watch 1000_1, a communication chipset for wirelessly communicating with the outside, and a circuit board in which memory and/or the like are mounted may be additionally arranged between the middle frame MF and the bottom cover BC.

The main body unit BP may sequentially include the bottom cover BC, the battery BR, the middle frame MF, the display panel 100, and the cover window CW.

The cover window CW is arranged on an upper portion of the display panel 100 to protect the display panel 100 and to transmit light emitted from the display panel 100. The cover window CW may include a light-blocking portion to block a portion of the light emitted from the display panel 100. The cover window CW may be made of a transparent plastic material, a glass material, or a reinforced glass material.

The cover window CW may be arranged to overlap the display panel 100 and cover the front of the display panel 100. The cover window CW generally has a shape similar to that of the display panel 100 in plan view, but its size may be larger than that of the display panel 100. For example, the cover window CW may protrude outward from the display panel 100. The planar shape of the cover window CW may be the same as that of the main body unit BP. For example, the planar shape of the cover window CW may be generally circular, but embodiments of the present disclosure are not limited thereto, for example, in one or more embodiments, the planar shape of the cover window CW may have one or more suitable shapes, for example, a polygon such as a square or an oval.

The middle frame MF is a joining member for joining the cover window CW and the bottom cover BC and is arranged between the cover window CW and the bottom cover BC. For example, the middle frame MF may include a bracket.

The bottom cover BC is a housing arranged under the display panel 100.

The bottom cover BC may include a central cover portion BCP and a peripheral portion BS arranged around the central cover portion BCP.

The central cover portion BCP is located at a center of the bottom cover BC and may be generally flat.

The peripheral portion BS may be arranged to surround the central cover portion BCP. The peripheral portion BS may be a portion that is bent and curved from the central cover portion BCP. The peripheral portion BS may be bent from an edge of the central portion CP. In one or more embodiments, the peripheral portion BS may include a curved surface having a set or predetermined curvature, and the other portion thereof may be flat. The degree (or angle) at which the peripheral portion BS is bent from the central cover portion BCP may be an obtuse angle, but embodiments of the present disclosure are not limited thereto, for example, the angle may also be a right angle or an acute angle.

A storage space BC-S may be formed by the central cover portion BCP and the peripheral portion BS. The battery BR may be placed in the storage space BC-S.

The battery BR may be connected to a circuit board on which a main processor and/or the like is mounted. The display panel 100 may be electrically connected to the circuit board to receive digital video signals, timing signals, power, and/or the like.

The bottom cover BC is placed on an outermost rear surface of the electronic device (i.e., smart watch 1000_1) and may include at least one of a plastic material, a metal material, or a glass material, and may include a color coating layer. For example, the bottom cover BC according to one embodiment may be a flat glass having a transparent, translucent, or opaque color coating layer.

The bottom cover BC according to one or more embodiments may have a same shape as the cover window CW and may include a glass material having a color coating layer. For example, the bottom cover BC according to one or more embodiments may have a structure symmetrical to the cover window CW with a middle frame MF in between and may include a transparent, translucent, or opaque color coating layer.

The wearing portion BD is a portion for fixing the main body unit BP to a user's wrist, for example, and may be one selected from among a strap, a chain, and a bracelet.

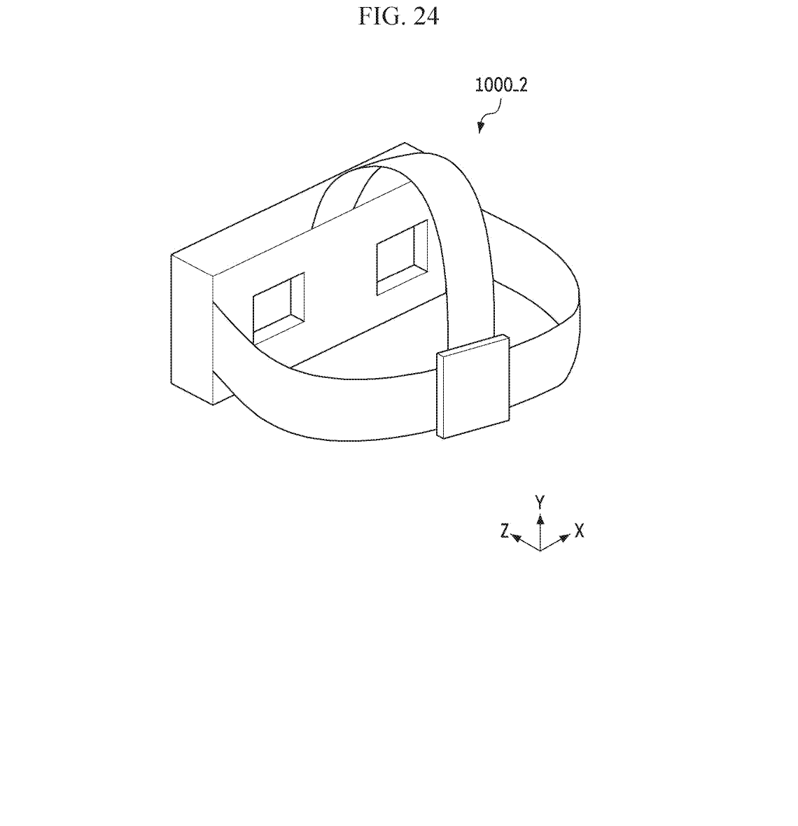

FIG. 24 is an example view of a virtual reality (VR) device including a display device according to one or more embodiments of the present disclosure.

Referring to FIG. 24, a head mounted display device 1000_2 according to one or more embodiments includes a display device housing, a housing cover, a first eyepiece, a second eyepiece, and a head mounted band.

The display device housing houses a display device, the head mounted display device 1000_2 according to one or more embodiments further include a first optical member arranged between a first display device and the first eyepiece.

The housing cover is placed to cover an open surface of the display device housing. The housing cover may include the first eyepiece at which a user’s left eye looks and the second eyepiece at which a user’s right eye looks.

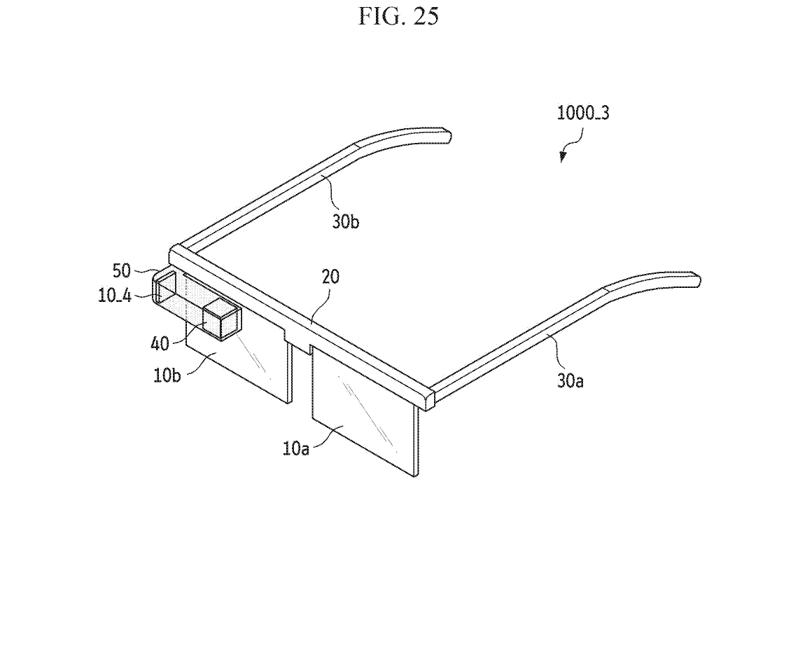

The head mounted band fixes the display device housing to a user’s head so that the first eyepiece and the second eyepiece of the housing cover are kept placed on the user’s left and right eyes, respectively. When the display device housing is implemented to be lightweight and small, the head mounted display device 1000_2 may include an eyeglass frame as illustrated in FIG. 25 instead of the head mounted band.

In addition, the head mounted display device 1000_2 may further include a battery for supplying power, an external memory slot for accommodating an external memory, and an external connection port and a wireless communication module for receiving an image source. The external connection port may be at least one of a universe serial bus (USB) terminal, a display port, or a high-definition multimedia interface (HDMI) terminal, and the wireless communication module may be at least one of a 5G communication module, a 4G communication module, a Wi-Fi module, or a Bluetooth module.

FIG. 25 is an example view of a VR device including a display device according to one or more embodiments of the present disclosure. FIG. 25 illustrates a VR device 1000_3 to which a display device 10_4 according to one or more embodiments has been applied.

Referring to FIG. 25, the VR device 1000_3 according to one or more embodiments may be a device in the form of glasses. The VR device 1000_3 according to one or more embodiments may include the display device 10_4, a left lens 10a, a right lens 10b, a support frame 20, eyeglass frame legs 30a and 30b, a reflective member 40, and a display device housing 50.

In FIG. 25, an embodiment in which the VR device 1000_3 is a glasses-type (kind) display device including the eyeglass frame legs 30a and 30b is illustrated as an example. For example, the VR device 1000_3 according to one or more embodiments is not limited to the one illustrated in FIG. 25 and may be applied in one or more suitable forms to one or more suitable other electronic devices.

The display device housing 50 may include the display device 10_4 and the reflective member 40. An image displayed on the display device 10_4 may be reflected by the reflective member 40 and provided to a user’s right eye through the right lens 10b. Accordingly, the user may view a VR image displayed on the display device 10_4 through the right eye.

Although the display device housing 50 is arranged at a right end of the support frame 20 in FIG. 25, embodiments of the present disclosure are not limited thereto. For example, in one or more embodiments, the display device housing 50 may also be arranged at a left end of the support frame 20. In these embodiments, an image displayed on the display device 10_4 may be reflected by the reflective member 40 and provided to the user’s left eye through the left lens 10a. Accordingly, the user may view a VR image displayed on the display device 10_4 through the left eye. In one or more embodiments, the display device housing 50 may be arranged at both (e.g., simultaneously) the right end and the left end of the support frame 20. In these embodiments, the user may view a VR image displayed on the display device 10_4 through both (e.g., simultaneously) the left eye and the right eye.

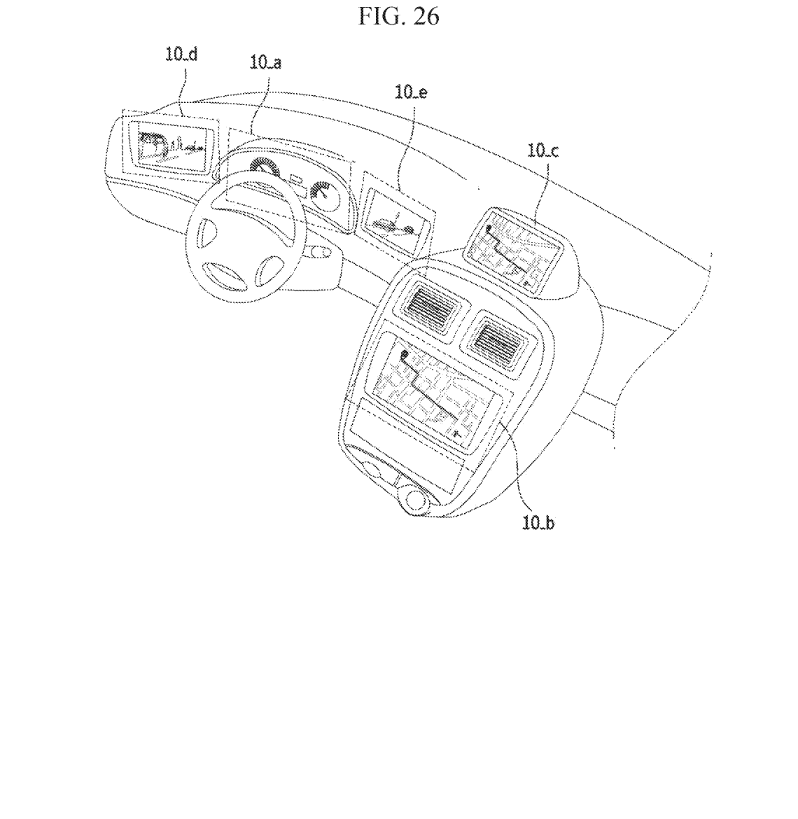

FIG. 26 is an example view illustrating a vehicle instrument cluster and center fascia including display devices according to one or more embodiments of the present disclosure. FIG. 26 illustrates a vehicle to which display devices 10_a through 10_e according to one or more embodiments have been applied.

Referring to FIG. 26, the display devices 10_a through 10_c according to one or more embodiments may be applied to an instrument cluster of the vehicle, a center fascia of the vehicle, or a center information display (CID) arranged on a dashboard of the vehicle. In addition, the display devices 10_d and 10_e according to one or more embodiments may be applied to room mirror displays that replace side mirrors of the vehicle.

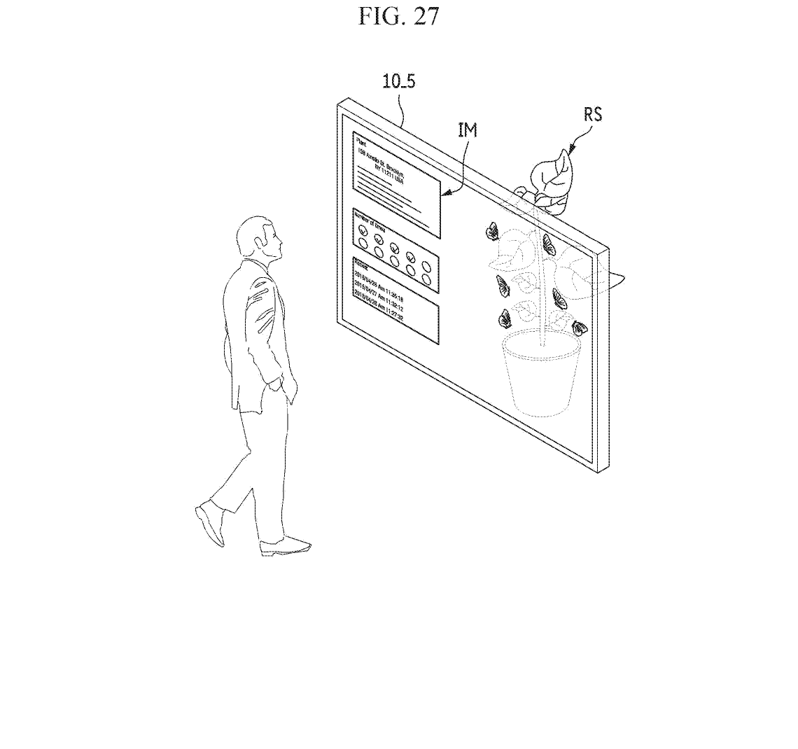

FIG. 27 is an example view of a transparent display device including a display device according to one or more embodiments of the present disclosure.

Referring to FIG. 27, a display device 10_5 according to one or more embodiments may be applied to a transparent display device. The transparent display device may be to transmit light while displaying an image IM. Therefore, a user located in front of the transparent display device may not only view the image IM displayed on the display device 10_5 but also view an object RS or the background located behind the transparent display device. When the display device 10_5 is applied to the transparent display device, a substrate of the display device 10_5 may include a light transmitting portion that can transmit light or may be made of a material that can transmit light.

It should be understood, however, that the aspects and features of embodiments of the present disclosure are not restricted to those set forth herein. The above and other aspects of the present disclosure will become more apparent to one of ordinary skill in the art to which the present disclosure pertains by referencing the claims, with equivalents thereof to be included therein. It is further understood that the scope of the present disclosure is defined by the appended claims and equivalents thereof rather than the detailed description described above, and all modifications and alterations derived from the claims and their equivalents fall within the scope of the present disclosure.

What is claimed is:

1. A display device comprising:
a substrate;
a transistor layer on the substrate;
a pixel electrode layer on the transistor layer;
a plurality of light emitting elements on the pixel electrode layer;
a plurality of light extraction structures apart from each other on the pixel electrode layer to overlap the plurality of light emitting elements;
a light blocking layer between the plurality of light extraction structures;
a reflective layer between each of the light extraction structures and the light blocking layer and around at least a portion of a side surface of each of the plurality of light extraction structures;
an organic layer on the light extraction structures and the light blocking layer;
a high refractive index layer on the organic layer to overlap the light blocking layer; and
a multi-lens layer overlapping the high refractive index layer and the light extraction structures on the organic layer,
wherein the multi-lens layer comprises:
one or more first type lenses overlapping a corresponding light extraction structure among the plurality of light extraction structures and having a first curvature; and
a plurality of second type lenses overlapping the high refractive index layer and having a second curvature different from the first curvature.

2. The display device of claim 1, wherein the second curvature is greater than the first curvature.

3. The display device of claim 1, wherein the plurality of second type lenses surrounds the one or more first type lenses.

4. The display device of claim 3, wherein the first type lens is arranged to overlap the light emitting element, and wherein the second type lens is arranged to overlap the light blocking layer.

5. The display device of claim 3, wherein a width of the first type lens is wider than a width of the second type lens, and
wherein a height of the first type lens is equal to or lower than a height of the second type lens.

6. The display device of claim 1, wherein the first type lens and the second type lens each independently have a planar shape selected from among a square, a circle, and an oval.

7. The display device of claim 1, wherein a refractive index of the high refractive index layer is higher than a refractive index of the organic layer.

8. The display device of claim 1, wherein the high refractive index layer is arranged to be around a periphery of the light emitting element and does not overlap the light emitting element.

9. The display device of claim 1, wherein the organic layer has a groove, and wherein the high refractive index layer is arranged in the groove.

10. The display device of claim 1, wherein the organic layer comprises a first organic layer to planarize the light extraction structure and the light blocking layer and a second organic layer that is arranged on a top surface of the light extraction structure to planarize the high refractive index layer.

11. The display device of claim 1, wherein each of the plurality of light emitting elements is covered by a corresponding light extraction structure among the plurality of light extraction structures, and
wherein a side surface of each of the plurality of light extraction structures comprises a reverse tapered slope.

12. The display device of claim 1, wherein each of the plurality of light extraction structures is around at least a portion of a side surface adjacent to a top surface of a corresponding light emitting element among the plurality of light emitting elements.

13. The display device of claim 1, wherein each of the plurality of light extraction structures comprises a scattering particle.

14. The display device of claim 1, wherein an upper edge of each of the plurality of light extraction structures has a rounded shape in a cross-section.

15. The display device of claim 14, wherein an upper edge adjacent to a top surface of each of the plurality of light extraction structures is not covered by the reflective layer.

16. The display device of claim 14, wherein the upper edge adjacent to a top surface of each of the plurality of light extraction structures is not covered by the light blocking layer.

17. The display device of claim 1, wherein the light emitting element comprises:
a conductive layer on a bottom surface of a first semiconductor layer;
an active layer on the first semiconductor layer;
a second semiconductor layer on the active layer;
a protective layer around the conductive layer, the first semiconductor layer, the active layer, and the second semiconductor layer;
a first contact electrode on the protective layer and connected to the conductive layer exposed without being covered by the protective layer; and
a second contact electrode on the protective layer and arranged in a hole penetrating the conductive layer, the first semiconductor layer, and the active layer.

18. The display device of claim 1,
wherein the light emitting element comprises:
a conductive layer on a bottom surface of a first semiconductor layer;
an active layer on the first semiconductor layer;
a second semiconductor layer on the active layer;
a protective layer around the conductive layer, the first semiconductor layer, the active layer, and the second semiconductor layer; and
a contact electrode arranged on the protective layer and connected to the conductive layer exposed without being covered by the protective layer,
wherein the pixel electrode layer comprises a pixel electrode connected to the contact electrode, and
wherein the display device further comprises a common electrode on the light emitting element.

19. An electronic device comprising:
a display panel;
a window on the display panel; and
a bottom cover below the display panel,
wherein the display panel comprises:
a substrate;
a transistor layer on the substrate;
a pixel electrode layer on the transistor layer;
a plurality of light emitting elements on the pixel electrode layer;
a plurality of light extraction structures apart from each other on the pixel electrode layer to overlap the plurality of light emitting elements;
a light blocking layer between the plurality of light extraction structures;
a reflective layer between each of the light extraction structures and the light blocking layer and around at least a portion of a side surface of each of the plurality of light extraction structures;
an organic layer on the light extraction structures and the light blocking layer;
a high refractive index layer on the organic layer to overlap the light blocking layer; and
a multi-lens layer overlapping the high refractive index layer and the light extraction structures on the organic layer,
wherein the multi-lens layer comprises:
one or more first type lenses overlapping a corresponding light extraction structure among the plurality of light extraction structures and having a first curvature; and
a plurality of second type lenses overlapping the high refractive index layer and having a second curvature different from the first curvature.

20. The electronic device of claim 19, further comprising:
a battery in a space of the bottom cover and to supply power to the display panel; and
a middle frame between the window and the bottom cover.
